(19) United States
(12) Patent Application Publication
(10) Pub. No.: US 2025/0176377 A1
(43) Pub. Date: May 29, 2025

(54) DISPLAY APPARATUS AND VEHICLE INCLUDING THE DISPLAY APPARATUS

(71) Applicant: Samsung Display Co., LTD., Yongin-si (KR)

(72) Inventors: Hyangyul KIM, Yongin-si (KR); Jaehong KIM, Yongin-si (KR); Hyunho JUNG, Yongin-si (KR); Heeseong JEONG, Yongin-si (KR)

(21) Appl. No.: 18/954,570

(22) Filed: Nov. 21, 2024

(30) Foreign Application Priority Data
Nov. 24, 2023 (KR) 10-2023-0165827

(51) Int. Cl. H10K 59/128; B60K 35/22; H10K 59/35; H10K 59/80

(52) U.S. Cl. CPC H10K 59/128; B60K 35/22; H10K 59/352; H10K 59/353; H10K 59/873; H10K 59/8792

(57) ABSTRACT

A display apparatus includes a first panel including a first substrate and a first display layer disposed on the first substrate, and a second panel including a second substrate disposed on the first panel and a second display layer disposed on the second substrate. The second panel includes a first display area defined by the second display layer, and at least one hole is defined through the second panel. The first panel includes a second display area defined by the first display layer and overlapping the at least one hole. An arrangement structure and an arrangement direction of a plurality of subpixels arranged in the first display area are respectively the same as an arrangement structure and an arrangement direction of a plurality of subpixels arranged in the second display area.

This application claims priority to Korean Patent Application No. 10-2023-0165827, filed on Nov. 24, 2023, and all the benefits accruing therefrom under 35 U.S.C. § 119, the content of which in its entirety is herein incorporated by reference.

### BACKGROUND

### 1. Field

One or more embodiments relate to a display apparatus and a vehicle including the display apparatus.

### 2. Description of the Related Art

Applications of display apparatuses have recently diversified. As display apparatuses have become thinner and lighter, their usage has gradually been extended, and as display apparatuses have been utilized in various fields, the demand for display apparatuses providing high-quality images has increased. Recently, display apparatuses have been provided inside vehicles to provide images to users sitting on a driver's seat or a passenger seat.

### SUMMARY

One or more embodiments include a display apparatus realizing high-quality images and a vehicle including the display apparatus. However, aspects of embodiments are not limited thereto, and the above characteristics do not limit the scope of embodiments according to the disclosure.

Additional aspects will be set forth in portion in the description which follows and, in part, will be apparent from the description, or may be learned by practice of the presented embodiments of the disclosure.

According to one or more embodiments, a display apparatus includes a first panel including a first substrate and a first display layer disposed on the first substrate, and a second panel including a second substrate disposed on the first panel, and a second display layer disposed on the second substrate. In such embodiments, the second panel includes a first display area defined by the second display layer, and at least one hole passing through the second panel is defined, and the first panel includes a second display area defined by the first display layer and overlapping the at least one hole. In such an embodiment, an arrangement structure and an arrangement direction of a plurality of subpixels arranged in the first display area are respectively the same as an arrangement structure and an arrangement direction of a plurality of subpixels arranged in the second display area.

In an embodiment, the plurality of subpixels may include a first subpixel which emits red light, a second subpixel which emits green light, and a third subpixel which emits blue light, and each of the first subpixel and the second subpixel may have a rectangular shape in a plan view.

In an embodiment, the third subpixel may have a square shape or chamfered square shape in a plan view.

In an embodiment, each of the first display area and the second display area may include a first pixel unit and a second pixel unit arranged adjacent to each other, and each of the first pixel unit and the second pixel unit may include the first subpixel, the second subpixel, and the third subpixel.

In an embodiment, the first pixel unit may have an arrangement structure in which a longer side of the first subpixel faces a longer side of the second subpixel and another longer side of the second subpixel faces one side of the third subpixel, and the second pixel unit may have an arrangement structure in which a longer side of the first subpixel faces a longer side of the second subpixel and a shorter side of the first subpixel and a shorter side of the second subpixel face one side of the third subpixel.

In an embodiment, the second panel may have longer sides each extending a first direction and shorter sides each extending in a second direction that intersects the first direction.

In an embodiment, the first pixel units may be consecutively arranged in the second direction, the second pixel units may be consecutively arranged in the second direction, and the first pixel units and the second pixel units may be arranged alternately in the first direction.

In an embodiment, the first pixel units may be consecutively arranged in the first direction, the second pixel units may be consecutively arranged in the first direction, and the first pixel units and the second pixel units may be arranged alternately in the second direction.

In an embodiment, the first panel may be disposed on the first display layer and further include a first light path control layer including a plurality of first light-shielding lines. In such an embodiment, the second panel may be disposed on the second display layer and further include a second light path control layer including a plurality of second light-shielding lines. In such an embodiment, in a plan view, the plurality of first light-shielding lines and the plurality of second light-shielding lines may each extend while being inclined at a same angle as each other.

In an embodiment, the at least one hole may have a polygonal shape or a circular shape.

In an embodiment, the first panel may further include a first encapsulation member covering the first display layer, and the second panel may further include a second encapsulation member covering the second display layer.

In an embodiment, the first encapsulation member may include an encapsulation substrate and a sealing member disposed between the encapsulation substrate and the first substrate, and the second encapsulation member may include at least one inorganic encapsulation layer and at least one organic encapsulation layer.

In an embodiment, each of the first encapsulation member and the second encapsulation member may include at least one inorganic encapsulation layer and at least one organic encapsulation layer.

In an embodiment, the display apparatus may further include an adhesive member interposed between the first panel and the second panel.

In an embodiment, the display apparatus may further include a cover window disposed on the second panel.

According to one or more embodiments, a vehicle includes side window glasses spaced apart from each other in a first direction, and a display apparatus disposed between the side window glasses. In such embodiments, the display apparatus includes a first panel including a first substrate and a first display layer disposed on the first substrate, and a second panel including a second substrate disposed on the first panel, and a second display layer disposed on the second substrate. In such embodiments, the second panel includes a first display area defined by the second display layer, and at least one hole passing through the second panel is defined, and the first panel includes a second display area defined by the first display layer and overlapping the at least one hole. In such embodiments, an arrangement structure and an arrangement direction of a plurality of subpixels arranged in the first display area are respectively the same as an arrangement structure and an arrangement direction of a plurality of subpixels arranged in the second display area.

In an embodiment, the first panel may be disposed on the first display layer and further include a first light path control layer including a plurality of first light-shielding lines. The second panel may be disposed on the second display layer and further include a second light path control layer including a plurality of second light-shielding lines. In a plan view, the plurality of first light-shielding lines and the plurality of second light-shielding lines may each extend while being inclined at a same angle as each other.

In an embodiment, the display apparatus may be disposed in a cluster located in front of a steering wheel.

In an embodiment, the first display area and the second display area may be independently driven.

In an embodiment, the display apparatus may display an image on the second display area in a driving mode, and display an image on both of the first display area and the second display area in a non-driving mode.

### BRIEF DESCRIPTION OF THE DRAWINGS

The above and other features of certain embodiments of the disclosure will be more apparent from the following description taken in conjunction with the accompanying drawings, in which:

FIG. 1 is a schematic view of the exterior of a vehicle according to an embodiment;

FIGS. 2A and 2B are schematic views of the interior of a vehicle according to an embodiment;

FIGS. 3A through 3C are schematic plan views of a display apparatus according to an embodiment;

FIG. 4 is a schematic cross-sectional view of the display apparatus of FIG. 3A taken along line I-I′;

FIG. 5 is an equivalent circuit diagram illustrating a display apparatus including an organic light-emitting diode and a subpixel circuit PC electrically connected to the organic light-emitting diode, according to an embodiment;

FIG. 6 is a schematic plan view of a first cluster panel included in a display apparatus according to an embodiment;

FIGS. 7A and 7B are schematic plan views of a portion of a display apparatus according to an embodiment, and are enlarged views of a region A of the display apparatus of FIG. 6;

FIG. 8 is a schematic cross-sectional view of a portion of a display apparatus according to an embodiment, and illustrates a schematic cross-section of the display apparatus of FIG. 7B taken along line II-II′;

FIG. 9 is a schematic plan view of a second cluster panel included in a display apparatus according to an embodiment;

FIGS. 10A and 10B are schematic plan views of a portion of a display apparatus according to an embodiment, and are enlarged views of a region B of the display apparatus of FIG. 9;

FIG. 11 is a schematic cross-sectional view of a portion of a display apparatus according to an embodiment, and illustrates a schematic cross-section of the display apparatus of FIG. 10B taken along line III-III′;

FIG. 12A is a layout diagram schematically showing locations of first cluster panels formed on a first substrate;

FIG. 12B is a layout diagram schematically showing locations of second cluster panels formed on a second substrate;

FIG. 13 is a schematic plan view of a display apparatus according to another embodiment; and

FIGS. 14A and 14B are schematic plan views of portions of a display apparatus according to another embodiment, respectively.

### DETAILED DESCRIPTION

The invention now will be described more fully hereinafter with reference to the accompanying drawings, in which various embodiments are shown. This invention may, however, be embodied in many different forms, and should not be construed as limited to the embodiments set forth herein. Rather, these embodiments are provided so that this disclosure will be thorough and complete, and will fully convey the scope of the invention to those skilled in the art.

As the disclosure allows for various changes and numerous embodiments, particular embodiments will be illustrated in the drawings and described in detail in the written description. Hereinafter, effects and features of the disclosure and a method for accomplishing them will be described more fully with reference to the accompanying drawings, in which embodiments of the disclosure are shown. The disclosure may, however, be embodied in many different forms and should not be construed as limited to the embodiments set forth herein.

One or more embodiments of the disclosure will be described below in more detail with reference to the accompanying drawings. Those components that are the same as or are in correspondence with each other are rendered the same reference numeral regardless of the figure number, and redundant explanations are omitted.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. Thus, reference to “an” element in a claim followed by reference to “the” element is inclusive of one element and a plurality of the elements. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items.

It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

It will be understood that when a layer, region, or component is referred to as being “on” another layer, region, or component, it can be directly or indirectly formed on the other layer, region, or component. That is, for example, intervening layers, regions, or components may be present therebetween. In contrast, when an element is referred to as being “directly on” another element, there are no intervening elements present.

Sizes of elements in the drawings may be exaggerated or reduced for convenience of explanation. For example, since sizes and thicknesses of components in the drawings are arbitrarily illustrated for convenience of explanation, embodiments are not limited thereto.

When a certain embodiment may be implemented differently, a specific process order may be performed differently from the described order. For example, two consecutively described processes may be performed substantially at the same time or performed in an order opposite to the described order.

It will also be understood that when a layer, region, or component is referred to as being “connected” or “coupled” to another layer, region, or component, it can be directly connected or coupled to the other layer, region, or component or intervening layers, regions, or components may be present. For example, when a layer, region, or component is referred to as being “electrically connected” or “electrically coupled” to another layer, region, or component, it can be directly electrically connected or coupled to the other layer, region, or component or intervening layers, regions, or components may be present.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within ±30%, 20%, 10% or 5% of the stated value.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

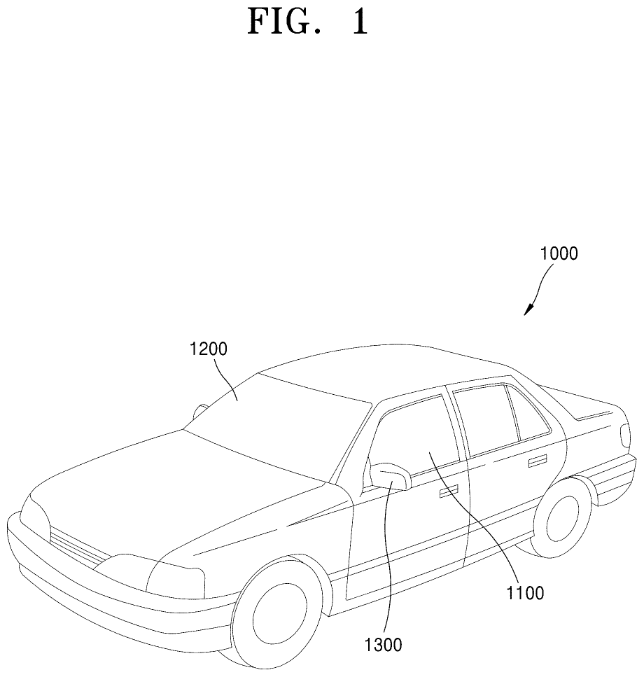

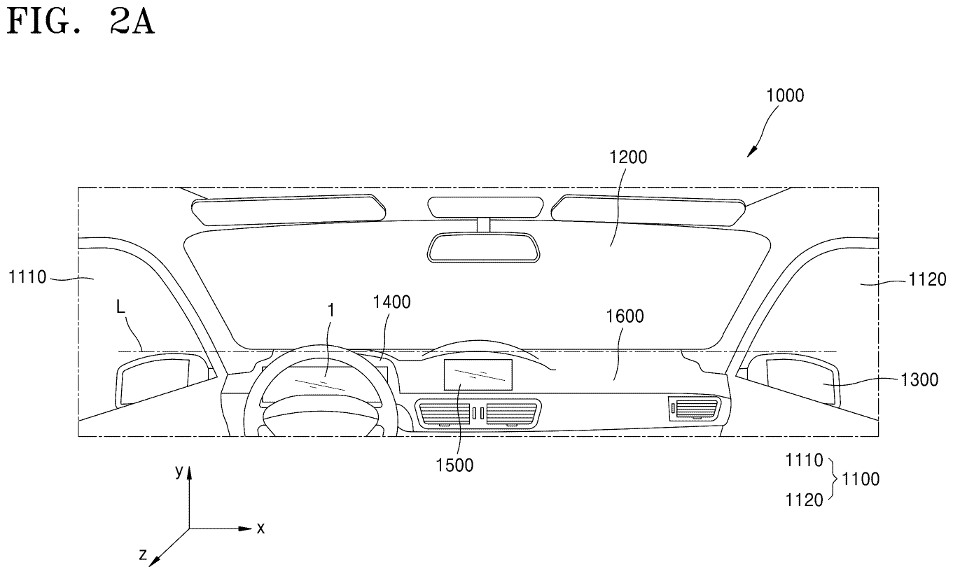

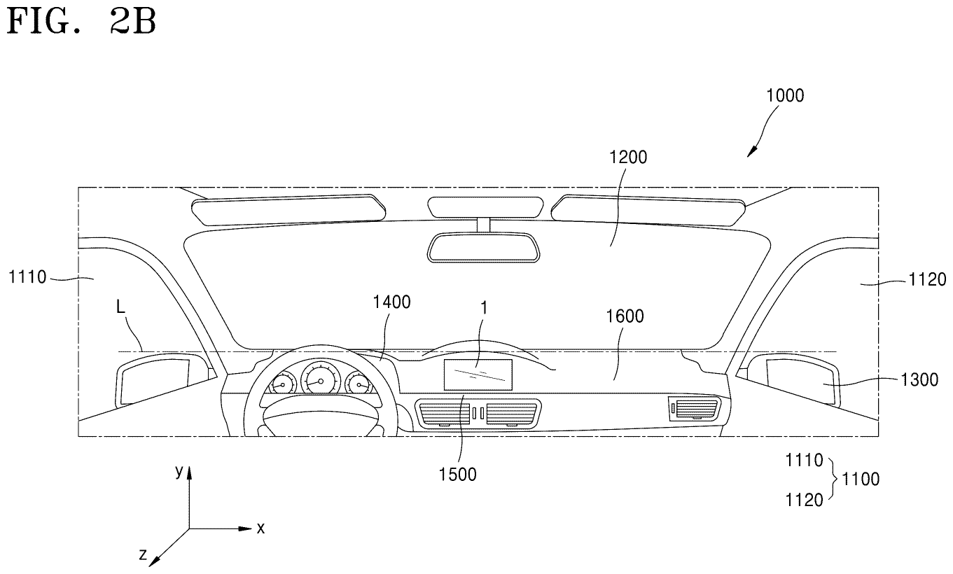

FIG. 1 is a schematic view of the exterior of a vehicle 1000 according to an embodiment. FIGS. 2A and 2B are schematic views of the interior of the vehicle 1000 according to an embodiment.

Referring to FIGS. 1, 2A, and 2B, in an embodiment, the vehicle 1000 may be any of various vehicles that move an object such as human beings, things, or animals from a departure point to a destination point. The vehicle 1000 may include a vehicle for traveling on a road or tracks, a vessel for sailing over a sea or river, and an airplane for flying in the sky by using the action of air.

The vehicle 1000 may travel on a road or track. The vehicle 1000 may move in a certain direction based on rotation of at least one wheel. In an embodiment, for example, the vehicle 1000 may include a three-wheeled or four-wheeled vehicle, a construction machine, a two-wheeled vehicle, a motor apparatus, a bicycle, and a train running on a track.

The vehicle 1000 may include a body and a chassis. The body has an interior and an exterior, and the chassis is the rest of parts except for the body and includes mechanical devices for driving installed thereon. The exterior of the body may include a front panel, a bonnet, a roof panel, a rear panel, a trunk, and a pillar disposed in a boundary between doors. The chassis of the vehicle 1000 may include, for example, a power generating device, a power transmitting device, a driving device, a steering device, a braking device, a suspension device, a transmission device, a fuel device, and front, rear, left, and right wheels.

In an embodiment, as shown in FIG. 2A, the vehicle 1000 may include a side window glass 1100, a front window glass 1200, a side mirror 1300, a cluster 1400, a center fascia 1500, a passenger seat dashboard 1600, and a display (display apparatus or display device) 1.

The side window glass 1100 and the front window glass 1200 may be defined by a pillar disposed between the side window glass 1100 and the front window glass 1200.

The side window glass 1100 may be disposed on the lateral sides of the vehicle 1000. According to an embodiment, the side window glass 1100 may be disposed on the door of the vehicle 1000. A plurality of side window glass 1100 may be disposed to face each other. According to an embodiment, the side window glass 1100 may include a first side window glass 1110 and a second side window glass 1120. The first side window glass 1110 may be disposed adjacent to the cluster 1400. The second side window glass 1120 may be disposed adjacent to the passenger seat dashboard 1600.

The side window glasses 1100 may be spaced apart from each other in a first direction (e.g., an x direction). In an embodiment, for example, the first side window glass 1110 may be spaced apart from the second side window glass 1120 in the x direction. In other words, an imaginary connection line L connecting the side window glasses 1100 may extend in the first direction (e.g., the x direction).

The front window glass 1200 may be disposed on the front of the vehicle 1000. The front window glass 1200 may be disposed between the side window glasses 1100 facing each other.

The side mirror 1300 may provide a rear view of the vehicle 1000. The side mirror 1300 may be disposed on the exterior of the body. A plurality of side mirrors 1300 may be included. One of the plurality of side mirrors 1300 may be disposed on the outer side of the first side window glass 1110. Another of the plurality of side mirrors 1300 may be disposed on the outer side of the second side window glass 1120.

The cluster 1400 may be positioned in front of a steering wheel. A tachometer, a speedometer, a coolant thermometer, a fuel gauge, a turn indicator light, a high beam indicator light, a warning light, a seat belt warning light, an odometer, an automatic transmission lever position indicator light, a door open warning light, an engine oil warning light, and/or a low fuel warning light may be disposed in the cluster 1400.

The center fascia 1500 may include a control panel including a plurality of buttons for adjusting an audio device, an air conditioning device, and a heater of seats. The center fascia 1500 may be disposed on one side of the cluster 1400.

The passenger seat dashboard 1600 may be spaced apart from the cluster 1400 with the center fascia 1500 therebetween. According to an embodiment, the cluster 1400 may be disposed to correspond to a driver seat (not shown), and the passenger seat dashboard 1600 may be disposed to correspond to a passenger seat (not shown). According to an embodiment, the cluster 1400 may be adjacent to the first side window glass 1110, and the passenger seat dashboard 1600 may be adjacent to the second side window glass 1120.

The display apparatus 1 may be disposed inside the vehicle 1000. The display apparatus 1 may be disposed between the side window glasses 1100. The display apparatus 1 may display images. According to an embodiment, the display apparatus 1 may be disposed on at least one selected from the cluster 1400, the center fascia 1500, and the passenger seat dashboard 1600.

Examples of the display apparatus 1 may include liquid crystal displays (LCDs), electrophoretic displays, organic light-emitting displays, inorganic light-emitting displays, field emission displays, surface-conduction electron-emitter displays, plasma displays, and cathode ray displays. For convenience of description, embodiments where the display apparatus 1 is an organic light-emitting display will hereinafter be described in detail, but various types of display apparatuses as described above may be used in embodiments.

Referring to FIG. 2A, in an embodiment, the display apparatus 1 may be disposed on the cluster 1400. In such an embodiment, the cluster 1400 may express driving information, etc. through the display apparatus 1. That is, the cluster 1400 may be implemented digitally. The digital cluster 1400 may display vehicle information and driving information by using images. In an embodiment, for example, a needle of a tachometer and a gauge, and various warning light icons may be displayed by using digital signals.

Light emitted from the display apparatus 1 may travel in a specific direction. In an embodiment, for example, the light emitted from the display apparatus 1 may travel to the driver seat. The light emitted from the display apparatus 1 may not travel toward the front window glass 1200. In another embodiment, for example, light emitted from the display apparatus 1 may travel to the front window glass 1200 at a relatively small ratio. In the case where the light emitted from the display apparatus 1 travels toward the front window glass 1200, the light emitted from the display apparatus 1 may be reflected by the front window glass 1200 to reach the driver seat. Accordingly, the driver may recognize images of the display apparatus 1 focused on the front window glass 1200, and a safety issue may be caused when driving as the images on the front window glass 1200 may distract a driver. According to an embodiment, light emitted from the display apparatus 1 disposed on the cluster 1400 may travel in a specific direction. Accordingly, light traveling toward the front window glass 1200 may be effectively reduced.

Referring to FIG. 2B, in an embodiment, the display apparatus 1 may be disposed on the center fascia 1500. According to an embodiment, the display apparatus 1 may display navigation information. According to an embodiment, the display apparatus 1 may display information regarding audio, video, or vehicle settings.

Light emitted from the display apparatus 1 may travel in a specific direction. In an embodiment, for example, the light emitted from the display apparatus 1 may travel to the driver seat. The light emitted from the display apparatus 1 may travel to the passenger seat. The light emitted from the display apparatus 1 may not travel toward the front window glass 1200. In another embodiment, for example, light emitted from the display apparatus 1 may travel to the front window glass 1200 at a relatively small ratio. In the case where the light emitted from the display apparatus 1 travels toward the front window glass 1200, the light emitted from the display apparatus 1 may be reflected by the front window glass 1200 to reach the driver seat. Accordingly, the driver may recognize images of the display apparatus 1 focused on the front window glass 1200, and may not recognize an object in the front direction, and thus, may not be safe when driving as the images on the front window glass 1200 may distract a driver. According to an embodiment, light emitted from the display apparatus 1 disposed on the center fascia 1500 may travel in a specific direction. Accordingly, light traveling toward the front window glass 1200 may be effectively reduced.

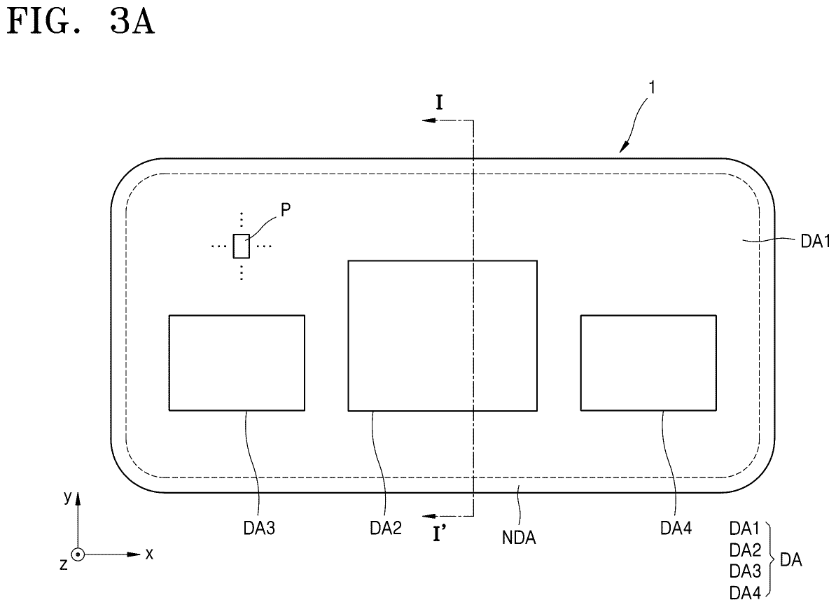

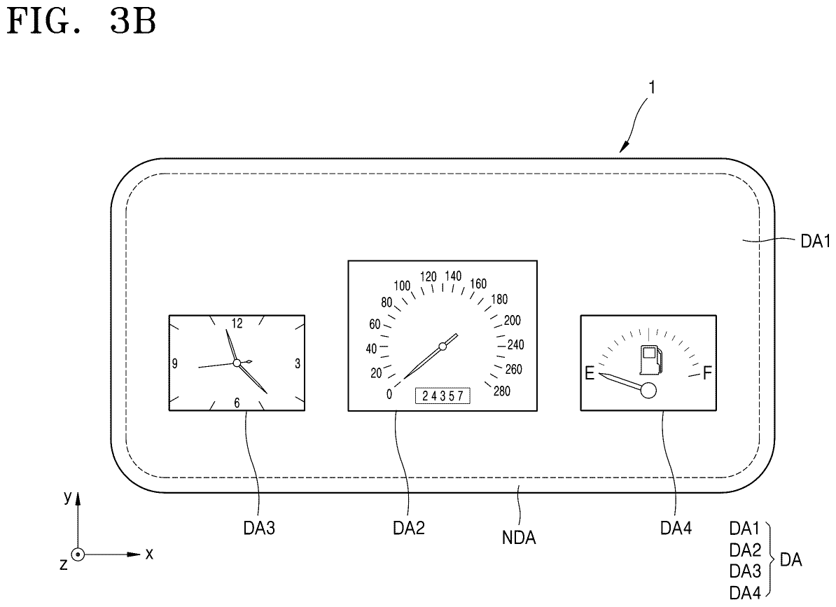

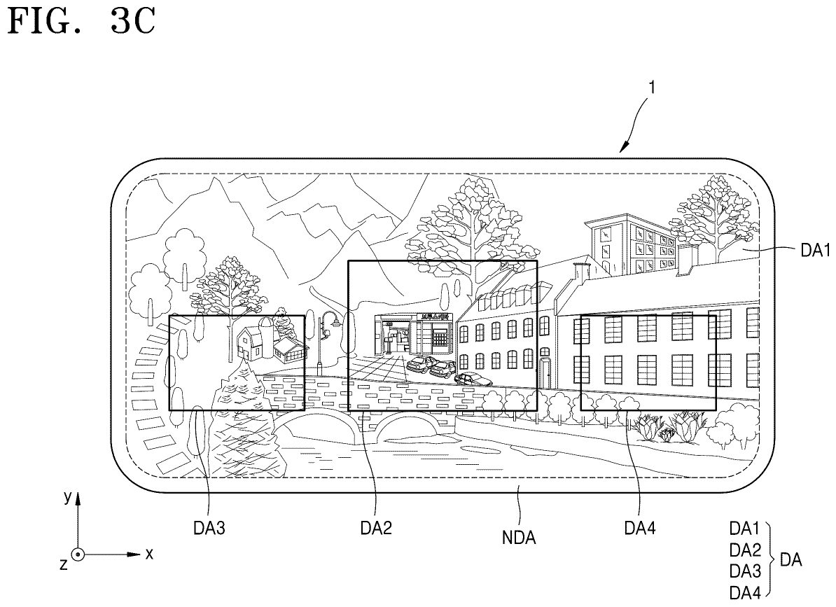

FIGS. 3A through 3C are schematic plan views of the display apparatus 1 according to an embodiment.

First, referring to FIG. 3A, an embodiment of the display apparatus 1 may include a display area DA and a non-display area NDA. A subpixel P may be arranged in the display area DA. The subpixel P may be disposed on a front surface of the display apparatus 1.

A plurality of subpixels P may be arranged on the display area DA. The subpixel P may be implemented as a light-emitting element. Light emitted from the subpixel P may travel in a specific one direction from the front surface of the display apparatus 1. The light emitted from the subpixel P may not travel in another specific direction from the front surface of the display apparatus 1. According to an embodiment, light emitted from the subpixel P may travel in a direction (e.g., a z direction) perpendicular to the front surface of the display apparatus 1. Light emitted from the subpixel P may travel in a direction (e.g., a direction intersecting the z direction) oblique to the front surface of the display apparatus 1. According to an embodiment, light emitted from the subpixel P may not have a component of at least one selected from the first direction (e.g., the x direction) and a second direction (e.g., a y direction).

The subpixel P may emit red light, green light, or blue light by using the light-emitting element. According to an embodiment, the subpixel P may emit red light, green light, blue light, or white light by using the light-emitting element. The subpixel PX may be defined by a light-emission area of the light-emitting element that emits one of red light, green light, blue light, and white light.

The subpixel P may include a light-emitting diode as a light-emitting element capable of emitting light of a certain color. The light-emitting diode may include an organic light-emitting diode including an organic material as an emission layer. In another embodiment, for example, the light-emitting diode may include an inorganic light-emitting diode. In another embodiment, for example, the light-emitting diode may include quantum dots as an emission layer. According to an embodiment, the size of the light-emitting diode may be microscale or nanoscale. In an embodiment, for example, the light-emitting diode may be a micro light-emitting diode. In another embodiment, for example, the light-emitting diode may be a nano light-emitting diode. The nano light-emitting diode may include gallium nitride (GaN). According to an embodiment, a color converting layer may be arranged on the nano light-emitting diode. The color converting layer may include quantum dots. For convenience of description, embodiments where the light-emitting diode includes an organic light-emitting diode will now be described in detail.

The display area DA may include a first display area DA1, a second display area DA2, a third display area DA3, and a fourth display area DA4. The second display area DA2, the third display area DA3, and the fourth display area DA4 may be disposed inside the first display area DA1 and may be entirely surrounded by the first display area DA1. The second display area DA2, the third display area DA3, and the fourth display area DA4 may have rectangular shapes in a plan view as shown in FIG. 3A. However, embodiments are not limited thereto and the second display area DA2, the third display area DA3, and the fourth display area DA4 may have polygonal shapes such as a pentagon.

The non-display area NDA may be an area that does not provide images. The non-display area NDA may surround at least a portion of the display area DA. According to an embodiment, the non-display area NDA may surround the entirety of the display area DA. A driver (driving circuit) or the like for providing an electrical signal or power to the subpixel P may be disposed in the non-display area NDA. The non-display area NDA may include a pad area where a pad is disposed.

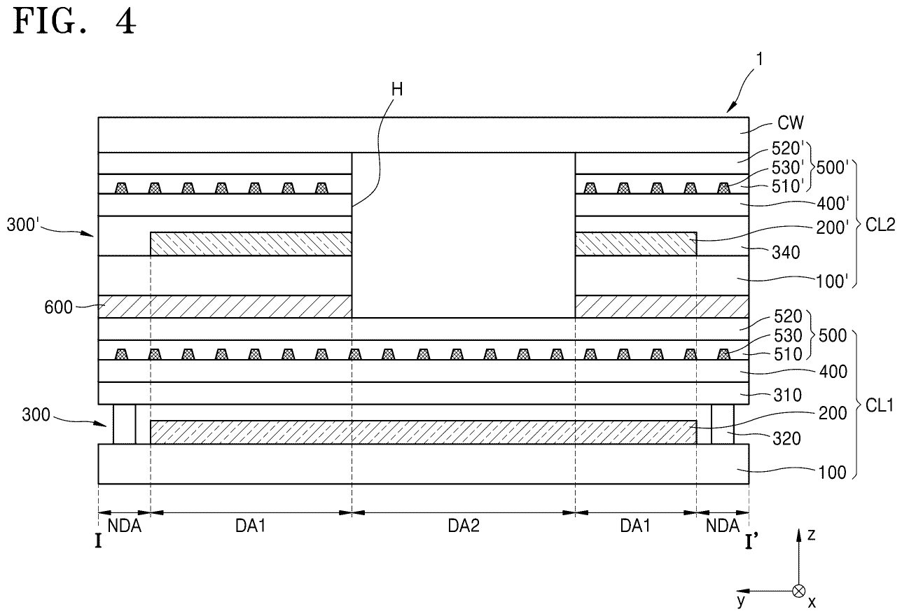

According to an embodiment, the display apparatus 1 may include a structure in which a first cluster panel CL1 (see FIG. 4) and a second cluster panel CL2 (see FIG. 4) are stacked. In such an embodiment, the first display area DA1 may be formed in the first cluster panel CL1 of FIG. 4, and the second display area DA2, the third display area DA3, and the fourth display area DA4 may be formed in the second cluster panel CL2 of FIG. 4. A stacked structure of the first cluster panel CL1 of FIG. 4 and the second cluster panel CL2 of FIG. 4 will be described in detail later with reference to FIG. 4.

The first display area DA1 of the first cluster panel CL1 of FIG. 4 may be driven independently of the second display area DA2, the third display area DA3, and the fourth display area DA4 of the second cluster panel CL2 of FIG. 4. In such an embodiment, the first display area DA1, the second display area DA2, the third display area DA3, and the fourth display area DA4 may not implement images at the same time, and may implement images individually.

Referring to FIG. 3B, a vehicle according to an embodiment may display images on the second display area DA2, the third display area DA3, and the fourth display area DA4 in a driving mode. In the driving mode, the second display area DA2, the third display area DA3, and the fourth display area DA4 may display vehicle information and driving information as images. For example, as shown in FIG. 3B, the second display area DA2 may implement a speedometer image, the third display area DA3 may implement a clock image, and the fourth display area DA4 may implement a fuel gauge image.

Referring to FIG. 3C, a vehicle according to an embodiment may display an image on all of the first display area DA1, the second display area DA2, the third display area DA3, and the fourth display area DA4 in a non-driving mode. In the non-driving mode, an image may be realized as the entire display area DA without distinguishing between the first display area DA1, the second display area DA2, the third display area DA3, and the fourth display area DA3. In an embodiment, for example, as shown in FIG. 3C, the display area DA may display one image in the entire area to allow a user to watch videos such as a movie or a drama in the non-driving mode.

FIG. 4 is a schematic cross-sectional view of the display apparatus 1 of FIG. 3A taken along line I-I′.

Referring to FIG. 4, an embodiment of the display apparatus 1 may include the first cluster panel CL1, the second cluster panel CL2, and a cover window CW. The second cluster panel CL2 may be disposed over the first cluster panel CL1 and may include at least one hole H defined through the second cluster panel CL2. The second cluster panel CL2 disposed on a relatively upper side may implement the first display area DA1 in an area excluding the hole H. The first cluster panel CL1 disposed on a relatively lower side may implement the second display area DA2 in an area overlapping the hole H.

First, the first cluster panel CL1 may include a first substrate 100, a first display layer 200, a first encapsulation member 300, a first anti-reflection layer 400, and a first light path control layer 500. The first substrate 100 may include glass, or may include polymer resin such as polyethersulfone, polyacrylate, polyetherimide, polyethylene naphthalate, polyethylene terephthalate, polyphenylene sulfide, polyimide, polycarbonate, cellulose triacetate, or cellulose acetate propionate. According to an embodiment, the first substrate 100 may have a multi-layered structure including a base layer including the aforementioned polymer resin and a barrier layer (not shown). The first substrate 100 including polymer resin may be flexible, rollable, or bendable.

The first display layer 200 may be disposed on the first substrate 100. The first display layer 200 may include a pixel circuit layer and a light-emitting element layer. The pixel circuit layer may include a pixel circuit. The pixel circuit may include a transistor and a storage capacitor. The light-emitting element layer may include a light-emitting element connected to the pixel circuit.

The first encapsulation member 300 may include an encapsulation substrate 310 and a sealing member 320. The encapsulation substrate 310 may be disposed on the first display layer 200. The sealing member 320 may be disposed between the first substrate 100 and the encapsulation substrate 310 in the non-display area NDA. An internal space between the first display layer 200 and the encapsulation substrate 310 may be sealed. The sealing member 320 may be sealant. According to another embodiment, the sealing member 320 may include a material cured by a laser beam. In an embodiment, for example, the sealing member 320 may include frit. In detail, the sealing member 320 may include an organic sealant, such as a urethane-based resin, an epoxy-based resin, or an acrylic resin, or an inorganic sealant. According to an embodiment, the sealing member 320 may include silicone. Urethane acrylate or the like may be used as the urethane-based rein. Butyl acrylate, ethylhexyl acrylate, or the like may be used as the acrylic resin. The sealing member 320 may include a material cured by heat.

The first anti-reflection layer 400 may be disposed on the first encapsulation member 300. The first anti-reflection layer 400 may reduce reflectivity of light (e.g., external light) that is incident from an external source toward the display apparatus 1. According to an embodiment, the first anti-reflection layer 400 may include a phase retarder and/or a polarizer. The phase retarder may be of a film type or liquid coating type, and may include a λ/2 phase retarder and/or a λ/4 phase retarder. The polarizer may also be of a film type or liquid coating type. The film type polarizer may include a stretchable synthetic resin film, and the liquid coating type polarizer may include liquid crystals arranged in a certain arrangement. The phase retarder and the polarizer may further include protective films, respectively.

According to another embodiment, the first anti-reflection layer 400 may include a black matrix and color filters. The color filters may be arranged according to the colors of light beams emitted by light-emitting elements. Each of the color filters may include a pigment or dye of a red, green, or blue color. Alternatively, each of the color filters may further include quantum dots in addition to the above-described pigment or dye. Alternatively, some of the color filters may not include the above-described pigment or dye, and may include scattered particles such as a titanium oxide.

According to another embodiment, the first anti-reflection layer 400 may include a destructive interference structure. The destructive interference structure may include a first reflection layer and a second reflection layer arranged on different layers. First reflected light and second reflected light respectively reflected by the first reflection layer and the second reflection layer may be destructively interfered with each other, and thus the reflectance of external light may be reduced.

The first light path control layer 500 may be disposed on the first anti-reflection layer 400. According to an embodiment, an adhesive layer may be disposed between the first light path control layer 500 and the first anti-reflection layer 400. The first light path control layer 500 may be configured to control a traveling direction of light emitted by the first display layer 200. In an embodiment, for example, a component in the second direction (e.g., the y direction) of the light emitted by the first display layer 200 may be at least partially removed by the first light path control layer 500. The first light path control layer 500 may include a first lower layer 510, a plurality of first light-shielding lines 530, and a first upper layer 520. The first lower layer 510 may include a transparent resin. According to an embodiment, the first lower layer 510 may include a plurality of grooves. The plurality of grooves may be arranged at regular intervals.

The plurality of first light-shielding lines 530 may fill the plurality of grooves, respectively. The plurality of first light-shielding lines 530 may each include a light-shielding material. In an embodiment, for example, the plurality of first light-shielding lines 530 may include a black material. The plurality of first light-shielding lines 530 may be formed by filling the plurality of grooves with black ink, respectively, and then radiating ultraviolet light thereto. The plurality of first light-shielding lines 530 may each extend in the first direction (e.g., the x direction). The plurality of first light-shielding lines 530 may be spaced apart from each other in the second direction (e.g., the y direction) perpendicular to the first direction (e.g., the x direction).

The first upper layer 520 may be disposed on the first lower layer 510 and the plurality of first light-shielding lines 530. The first upper layer 520 may include a polymer resin. In an embodiment, for example, the first upper layer 520 may include polycarbonate.

An adhesive member 600 may be disposed on the first light path control layer 500. The adhesive member 600 may be interposed between the first cluster panel CL1 and the second cluster panel CL2 to bond the first cluster panel CL1 with the second cluster panel CL2. The adhesive member 600 may include an organic adhesive layer such as pressure sensitive adhesive (PSA), optically clear adhesive (OCA), or optical clear resin (OCR). However, embodiments are not limited thereto, and the adhesive member 600 may include an adhesive material such as a polyurethane-based, polyacrylic-based, polyester-based, polyepoxy-based, or polyvinyl acetate-based material.

The second cluster panel CL2 may be disposed on the adhesive member 600. The second cluster panel CL2 may include a second substrate 100′, a second display layer 200′, a second encapsulation member 300′, a second anti-reflection layer 400′, and a second light path control layer 500′. Similar to the first substrate 100, the second substrate 100′ may include glass, or may include polymer resin such as polyethersulfone, polyacrylate, polyetherimide, polyethylene naphthalate, polyethylene terephthalate, polyphenylene sulfide, polyimide, polycarbonate, cellulose triacetate, or cellulose acetate propionate.

The second display layer 200′ may be disposed on the second substrate 100′. Similar to the first display layer 200, the second display layer 200′ may include a pixel circuit layer and a light-emitting element layer. The pixel circuit layer may include a pixel circuit, and the light-emitting element layer may include a light-emitting element connected to the pixel circuit.

The second encapsulation member 300′ may include an encapsulation layer covering the second display layer 200′. The second encapsulation member 300′ may include at least one inorganic encapsulation layer and at least one organic encapsulation layer 340. The at least one inorganic encapsulation layer and the at least one organic encapsulation layer 340 may be alternately stacked. The at least one inorganic encapsulation layer may include at least one inorganic material selected from aluminum oxide (Al₂O₃), titanium oxide (TiO₂), tantalum oxide (Ta₂O₅), zinc oxide (ZnOₓ), silicon oxide (SiO₂), silicon nitride (SiNₓ), and silicon oxynitride (SiON). The zinc oxide (ZnOx) may include a zinc oxide (ZnO) and/or a zinc peroxide (ZnO2). The at least one organic encapsulation layer 340 may include a polymer-based material. Examples of the polymer-based material may include an acrylic resin, an epoxy-based resin, polyimide, and polyethylene. According to an embodiment, the at least one organic encapsulation layer 340 may include acrylate.

The second anti-reflection layer 400′ and the second light path control layer 500′ may be disposed on the second encapsulation member 300′. The second anti-reflection layer 400′ may include substantially the same material as the first anti-reflection layer 400, and the second light path control layer 500′ may also include substantially the same structure and substantially the same material as the first light path control layer 500. In an embodiment, for example, the second light path control layer 500′ may include a second lower layer 510′, a plurality of second light-shielding lines 530′, and a second upper layer 520′.

The cover window CW may be disposed on the second light path control layer 500′. The cover window CW transmits an image from the first cluster panel CL1 and the second cluster panel CL2 and also relieves external shock, thereby effectively preventing the first cluster panel CL1 and the second cluster panel CL2 from being damaged or malfunctioning due to the external shock. The cover window CW may include at least one of glass, sapphire, and plastic. The cover window CW may be, for example, ultra-thin tempered glass (e.g., ultra-thin glass (UTG)) or colorless polyimide (CPI).

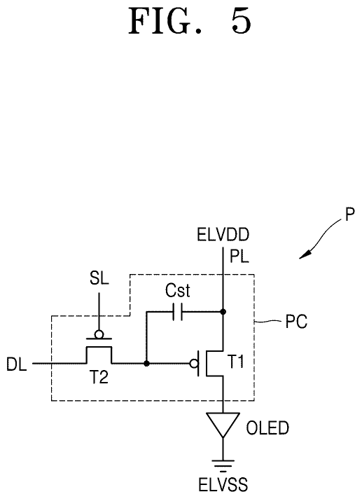

FIG. 5 is an equivalent circuit diagram illustrating a display apparatus including an organic light-emitting diode OLED and a subpixel circuit PC electrically connected to the organic light-emitting diode OLED, according to an embodiment.

Referring to FIG. 5, in an embodiment, each subpixel P may include the subpixel circuit P, and the organic light-emitting diode OLED as a display element. The subpixel circuit PC may include a driving transistor T1, a switching transistor T2, and a storage capacitor Cst. The subpixel P may emit, for example, one selected from red light, green light, blue light, and white light, via the organic light-emitting diode OLED.

The switching transistor T2 may be connected to a scan line SL and a data line DL, and may transmit, to the driving transistor T1, a data signal or data voltage received via the data line DL in response to a scan signal or switching voltage received via the scan line SL. The storage capacitor Cst may be connected to the switching transistor T2 and a driving voltage line PL, and may store a voltage corresponding to a difference between a voltage received from the switching transistor T2 and a first power supply voltage ELVDD supplied to the driving voltage line PL.

The driving transistor T1 may be connected to the driving voltage line PL and the storage capacitor Cst, and may control a driving current flowing from the driving voltage line PL to the organic light-emitting diode OLED, based on a voltage value stored in the storage capacitor Cst. The organic light-emitting diode OLED may emit light having a certain brightness corresponding to the driving current. A common electrode (for example, a cathode) of the organic light-emitting diode OLED may receive a second power supply voltage ELVSS.

In an embodiment, as shown in FIG. 5, the subpixel circuit PC includes two transistors and one storage capacitor. However, according to another embodiment, the subpixel circuit PC may include three or more transistors.

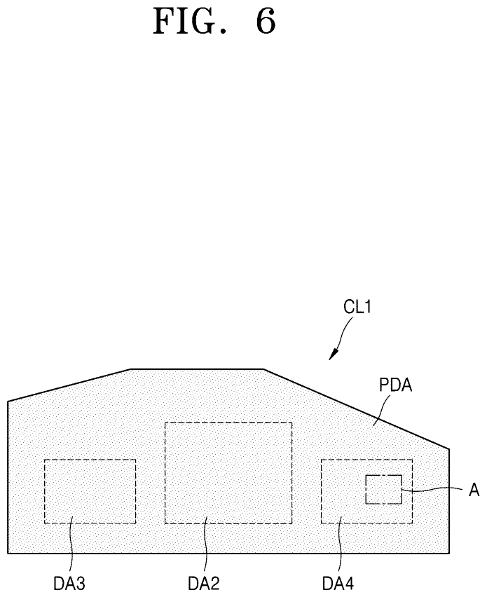

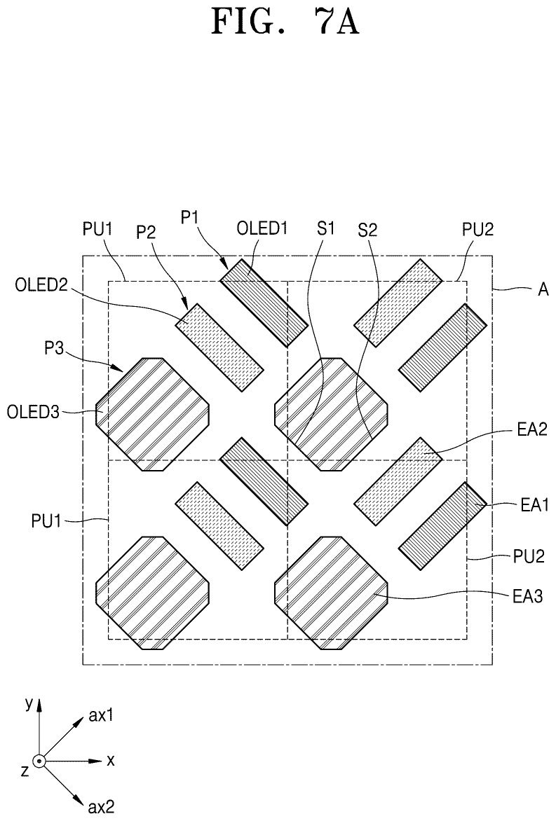

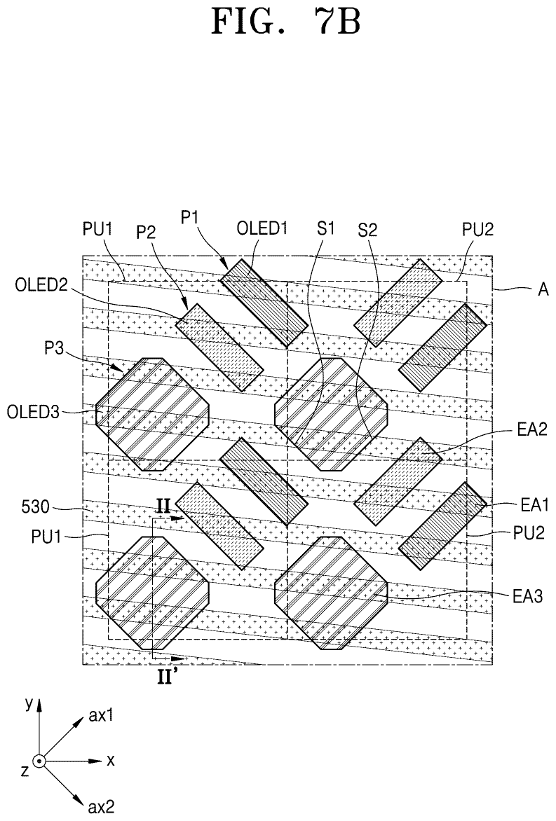

FIG. 6 is a schematic plan view of the first cluster panel CL1 included in a display apparatus according to an embodiment. FIGS. 7A and 7B are schematic plan views of a portion of a display apparatus according to an embodiment, are is enlarged views of a region A of the display apparatus of FIG. 6.

In an embodiment, referring to FIG. 6, the first cluster panel CL1 may include the second display area DA2, the third display area DA3, the fourth display area DA4, and a peripheral display area PDA. The second display area DA2, the third display area DA3, and the fourth display area DA4 may be located in a center portion of the first cluster panel CL1, and may be entirely surrounded by the peripheral display area PDA.

The second display area DA2, the third display area DA3, and the fourth display area DA4 may be areas that overlap at least one hole H (see FIG. 4) of the second cluster panel CL2 (see FIG. 4), which will be described later, and the peripheral display area PDA may be an area that does not overlap the at least one hole H (see FIG. 4) in the second cluster panel CL2 (see FIG. 4). In other words, the area of the first cluster panel CL1 that overlaps the second cluster panel CL2 (see FIG. 4) may be the peripheral display area PDA. Because a user looks at the display apparatus 1 (see FIG. 4) from the front surface of the second cluster panel CL2, an image may be implemented on the second display area DA2, the third display area DA3, and the fourth display area DA4, which are areas overlapping the at least one hole H in the second cluster panel CL2 (see FIG. 4).

In an embodiment, referring to FIG. 7A, a plurality of subpixels P (see FIG. 3A) may be arranged in each of the second display area DA2, the third display area DA3, and the fourth display area DA4. The plurality of subpixels P (see FIG. 3A) may include a first subpixel P1, a second subpixel P2, and a third subpixel P3 that emit light of different colors, respectively. Each of the first subpixel P1, the second subpixel P2, and the third subpixel P3 may be provided in plurality.

The first subpixel P1 may emit light in a first wavelength band. In an embodiment, for example, the first subpixel P1 may emit light with a wavelength in a range from about 630 nanometers (nm) to about 780 nm. In other words, the first subpixel P1 may emit light in a red wavelength band. The first subpixel P1 may be defined by a first emission area EA1 formed by a light-emitting element. In an embodiment, for example, the first emission area EA1 formed by a first organic light-emitting diode OLED1 may define the first subpixel P1.

The second subpixel P2 may emit light in a second wavelength band. In an embodiment, for example, the second subpixel P2 may emit light with a wavelength in a range from about 495 nm to about 570 nm. In other words, the second subpixel P2 may emit light in a green wavelength band. The second subpixel P2 may be defined by a second emission area EA2 formed by a light-emitting element. In an embodiment, for example, the second emission area EA2 formed by a second organic light-emitting diode OLED2 may define the second subpixel P2.

According to an embodiment, the first subpixel P1 and the second subpixel P2 may each have a rectangular shape. In other words, the first subpixel P1 and the second subpixel P2 may each have longer sides and shorter sides that intersect the longer sides, as shown in FIG. 7A. In such an embodiment, the longer side and the shorter side may be arranged to be tilted in different directions with respect to at least one of the first direction (e.g., the x direction) and the second direction (e.g., the y direction), respectively. In such an embodiment, the first subpixel P1 and the second subpixel P2 may be tilted to form an angle of 45 degrees with respect to either the first direction (e.g., the x direction) or the second direction (e.g., the y direction). In an embodiment, for example, at least one of the shorter and longer sides of each of the first subpixel P1 and the second subpixel P2 may form an angle of 45 degree with respect to an imaginary straight lines connecting the centers of a plurality of third subpixels P3 arranged in the first direction (e.g., the x direction).

The third subpixel P3 may emit light in a third wavelength band. In an embodiment, for example, the third subpixel P3 may emit light with a wavelength in a range from about 450 nm to about 495 nm. In other words, the third subpixel P3 may emit light in a blue wavelength band. The third subpixel P3 may be defined by a third emission area EA3 formed by a light-emitting element. In an embodiment, for example, the third emission area EA3 formed by a third organic light-emitting diode OLED3 may define the third subpixel P3.

According to an embodiment, the third subpixel P3 may have a square or chamfered square shape. That is, the third subpixel P3 may have a first side S1 and a second side S2 that intersects the first side S1, as shown in FIG. 7A. In such an embodiment, the first side S1 and the second side S2 may be arranged to be tilted in different directions with respect to at least one of the first direction (e.g., the x direction) and the second direction (e.g., the y direction), respectively. In an embodiment, for example, the second side S2 may refer to as a side extending based on a third direction (e.g., an ax1 direction) forming positive 45 degrees with respect to the first direction (e.g., the x direction), and the first side S1 may refer to a side extending in a fourth direction (e.g., an ax2 direction) forming negative 45 degrees with respect to the first direction (e.g., the x direction). Accordingly, the third subpixel P3 may be arranged in a diamond shape based on one of the first direction (e.g., the x direction) or the second direction (e.g., the y direction).

A first pixel unit PU1 and a second pixel unit PU2 may be disposed in each of the second display area DA2, the third display area DA3, and the fourth display area DA4. The first pixel unit PU1 and the second pixel unit PU may be disposed adjacent to each other. The first pixel unit PU1 and the second pixel unit PU2 may define a subpixel assembly in which a plurality of subpixels P (see FIG. 3) arranged according to a pixel array structure are grouped in a preset unit. That is, the first pixel unit PU1 and the second pixel unit PU2 may each be a minimum unit sub-pixel assembly that repeats in a certain pixel array structure. Each of the first pixel unit PU1 and the second pixel unit PU2 may be a subpixel assembly including the first subpixel P1 that emits red light, the second subpixel P2 that emits green light, and the third subpixel P3 that emits blue light.

According to an embodiment, the first pixel unit PU1 may have a structure in which a longer side of the first subpixel P1 faces a longer side of the second subpixel P2 and another longer side of the second subpixel P2 faces one side of the third subpixel P3. In the first pixel unit PU1, the third subpixel P3, the second subpixel P2, and the first subpixel P1 may be sequentially arranged in the third direction (e.g., the ax1 direction). In other words, the longer sides of the first subpixel P1 and the longer sides of the second subpixel P2 may be parallel to the first side S1 of the third subpixel P3 extending in a fourth direction (e.g., an ax2 direction).

According to an embodiment, the second pixel unit PU2 may have a structure in which a longer side of the first subpixel P1 faces a longer side of the second subpixel P2 and a shorter side of the first subpixel P1 and a shorter side of the second subpixel P2 face one side of the third subpixel P3. In other words, the shorter sides of the first subpixel P1 and the shorter sides of the second subpixel P2 may be parallel to the first side S1 of the third subpixel P3 extending in the fourth direction (e.g., the ax2 direction).

In such an embodiment, the first pixel unit PU1 and the second pixel unit PU2 may be repeatedly arranged within the second display area DA2, the third display area DA3, and the fourth display area DA4. According to an embodiment, the first pixel units PU1 may be consecutively arranged in the second direction (e.g., the y direction), and the second pixel units PU2 may also be consecutively arranged in the second direction (e.g., the y direction). The first pixel units PU1 and the second pixel units PU2 may be alternately arranged in the first direction (e.g., the x direction).

in an embodiment, referring to FIG. 7B, the first cluster panel CL1 may include a plurality of first light-shielding lines 530. The plurality of first light-shielding lines 530 may each extend generally in the first direction (e.g., the x direction). According to an embodiment, the plurality of first light-shielding lines 530 may each extend in a direction at an angle of about 5 degrees or less with respect to the first direction (e.g., the x direction).

The plurality of first light-shielding lines 530 may be spaced apart from each other at constant intervals in the second direction (e.g., the y direction). The constant interval may be a distance between two first light-shielding lines 530 adjacent to each other in the second direction (e.g., the y direction). In some embodiments, the plurality of first light-shielding lines 530 may be spaced apart at intervals in a range from about 30 micrometers (μm) to about 60 μm, and a width of each of the plurality of first light-shielding lines 530 may be about 10 μm.

The plurality of first light-shielding lines 530 may control light emitted by the first subpixel P1, the second subpixel P2, and the third subpixel P3 to proceed in a specific direction. In an embodiment, for example, a second direction (e.g., the y direction) component of the light emitted by the first subpixel P1, the second subpixel P2, and the third subpixel P3 may be removed by the plurality of first light-shielding lines 530.

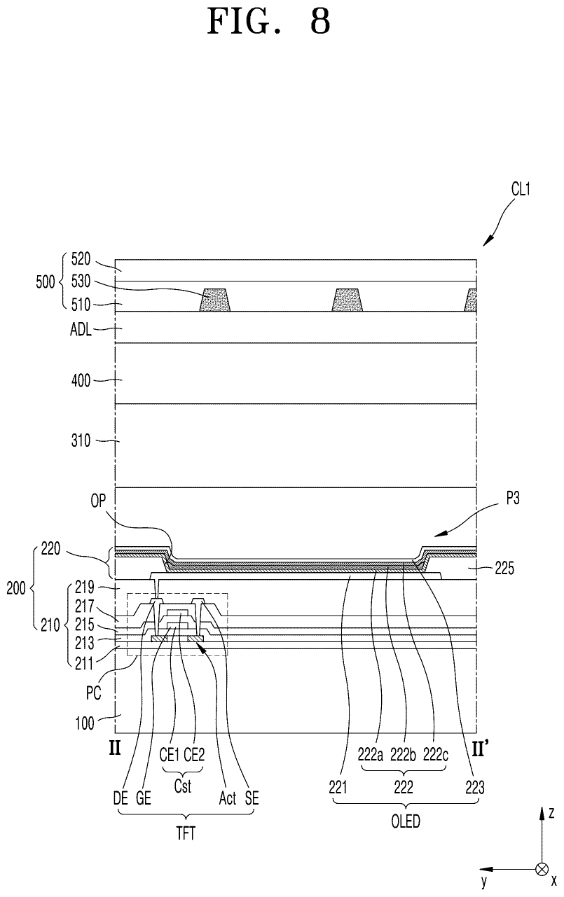

FIG. 8 is a schematic cross-sectional view of a portion of a display apparatus according to an embodiment, and illustrates a schematic cross-section of the display apparatus of FIG. 7B taken along line II-II′. FIG. 8 is a schematic cross-sectional view of a portion of the first cluster panel CL1, and reference numerals in FIG. 8 that are the same as or similar to the reference numerals in FIG. 4 denote the same or like elements, and thus any repetitive detailed descriptions thereof will be omitted.

Referring to FIG. 8, in an embodiment, the first cluster panel CL1 may include a first substrate 100, a first display layer 200, the first encapsulation member 300 of FIG. 4, a first anti-reflection layer 400, a first adhesive layer ADL, and a first light path control layer 500. The first display layer 200 may be disposed on the first substrate 100. The first display layer 200 may include a pixel circuit layer 210 and a light-emitting element layer 220. The pixel circuit layer 210 may include a buffer layer 211, a first gate insulating layer 213, a second gate insulating layer 215, an interlayer insulating layer 217, an organic insulating layer 219, and a subpixel circuit PC. The subpixel circuit PC may include a thin-film transistor TFT and a storage capacitor Cst. The thin-film transistor TFT may include a semiconductor layer Act, a gate electrode GE, a source electrode SE, and a drain electrode DE.

The buffer layer 211 may be disposed on the first substrate 100. The buffer layer 211 may include an inorganic insulating material, such as silicon nitride (SiNx), silicon oxynitride (SiON), or silicon oxide (SiO₂), and may have a single-layer or multi-layer structure including at least one selected from the aforementioned inorganic insulating materials.

The semiconductor layer Act may be arranged on the buffer layer 211. The semiconductor layer Act may include polysilicon. Alternatively, the semiconductor layer Act may include, for example, amorphous silicon, an oxide semiconductor, or an organic semiconductor. The semiconductor layer Act may include a channel region, and a source region and a drain region respectively arranged on both opposing sides of the channel region.

The first gate insulating layer 213 may be disposed on the semiconductor layer Act and the buffer layer 211. The first gate insulating layer 213 may include an inorganic insulating material, such as silicon oxide (SiO₂), silicon nitride (SiNₓ), silicon oxynitride (SiON), aluminum oxide (Al₂O₃), titanium oxide (TiO₂), tantalum oxide (Ta₂O₅), hafnium oxide (HfO₂), or zinc oxide (ZnOₓ). The zinc oxide (ZnOₓ) may include a zinc oxide (ZnO) and/or a zinc peroxide (ZnO₂).

The gate electrode GE may be disposed on the first gate insulating layer 213. The gate electrode GE may overlap the channel region. The gate electrode GE may include a low resistance metal material. The gate electrode GE may include a conductive material including molybdenum (Mo), aluminum (Al), copper (Cu), or titanium (Ti), and may have a single-layer or multi-layer structure including at least one selected from the aforementioned materials.

The second gate insulating layer 215 may be disposed on the gate electrode GE and the first gate insulating layer 213. Similar to the first gate insulating layer 213, the second gate insulating layer 215 may include an inorganic insulating material, such as silicon oxide (SiO₂), silicon nitride (SiNₓ), silicon oxynitride (SiON), aluminum oxide (Al₂O₃), titanium oxide (TiO₂), tantalum oxide (Ta₂O₅), hafnium oxide (HfO₂), or zinc oxide (ZnOₓ).

An upper electrode CE2 of the storage capacitor Cst may be disposed on the second gate insulating layer 215. The upper electrode CE2 may overlap the gate electrode GE located therebelow. In this case, the gate electrode GE and the upper electrode CE2 overlapping each other with the second gate insulating layer 215 therebetween may constitute the storage capacitor Cst. In other words, the gate electrode GE may function as a lower electrode CE1 of the storage capacitor Cst. According to an embodiment, the storage capacitor Cst and the thin-film transistor TFT may overlap each other. According to some embodiments, the storage capacitor Cst and the thin-film transistor TFT may not overlap each other. The upper electrode CE2 may include aluminum (Al), platinum (Pt), palladium (Pd), silver (Ag), magnesium (Mg), gold (Au), nickel (Ni), neodymium (Nd), iridium (Ir), chromium (Cr), calcium (Ca), molybdenum (Mo), titanium (Ti), tungsten (W), and/or copper (Cu), and may have a single layer or multi-layer structure including at least one selected from the aforementioned materials.

The interlayer insulating layer 217 may be disposed on the upper electrode CE2 and the second gate insulating layer 215. The interlayer insulating layer 217 may include silicon oxide (SiO₂), silicon nitride (SiNₓ), silicon oxynitride (SiON), aluminum oxide (Al₂O₃), titanium oxide (TiO₂), tantalum oxide (Ta₂O₅), hafnium oxide (HfO₂), zinc oxide (ZnOₓ), or the like. The interlayer insulating layer 217 may have a single layer or multi-layer structure including at least one selected from the aforementioned inorganic insulating materials.

The drain electrode DE and the source electrode SE may be disposed on the interlayer insulating layer 217. The drain electrode DE and the source electrode SE may be electrically connected to the semiconductor layer Act. The drain electrodes DE and the source electrode SE may include a highly conductive material. Each of the drain electrode DE and the source electrode SE may include a conductive material including Mo, Al, Cu, or Ti, and may have a multi-layer or single layer structure including at least one selected from the aforementioned materials. According to an embodiment, the drain electrodes DE and the source electrode SE may have a multi-layer structure of Ti/Al/Ti.

The organic insulating layer 219 may be disposed on the drain electrode DE, the source electrode SE, and the interlayer insulating layer 217. The organic insulating layer 219 may include an organic insulating material, such as a commercial polymer (such as PMMA or PS), a polymer derivative having a phenol-based group, an acrylic polymer, an imide-based polymer, an acryl ether-based polymer, an amide-based polymer, a fluorine-based polymer, a p-xylene-based polymer, a vinyl alcohol-based polymer, or a blend thereof. According to some embodiments, the organic insulating layer 219 may include a first organic insulating layer and a second organic insulating layer.

The light-emitting element layer 220 may be disposed on the pixel circuit layer 210. The light-emitting element layer 220 may be disposed on the organic insulating layer 219. The light-emitting element layer 220 may include a light-emitting element that implements a subpixel. In an embodiment, for example, the light-emitting element layer 220 may define an organic light-emitting diode OLED. The light-emitting element layer 220 may define the first organic light-emitting diode OLED1 of FIG. 7A, the second organic light-emitting diode OLED2 of FIG. 7A, and the third organic light-emitting diode OLED3 of FIG. 7A. In FIG. 8, the organic light-emitting diode OLED may implement the third subpixel P3.

The organic light-emitting diode OLED may include a pixel electrode 221, an intermediate layer 222, and an opposite electrode 223. The pixel electrode 221 may be electrically connected to the thin-film transistor TFT through a contact hole of the organic insulating layer 219. The pixel electrode 221 may include conductive oxide such as indium tin oxide (ITO), indium zinc oxide (IZO), zinc oxide (ZnO), indium oxide (In₂O₃), indium gallium oxide (IGO), or aluminum zinc oxide (AZO). According to another embodiment, the pixel electrode 221 may include a reflective layer including, for example, silver (Ag), magnesium (Mg), aluminum (Al), platinum (Pt), palladium (Pd), gold (Au), nickel (Ni), neodymium (Nd), iridium (Ir), chromium (Cr), or a compound of these materials. According to another embodiment, the pixel electrode 221 may further include a film formed of ITO, IZO, ZnO, or In₂O₃ over/under the reflective layer. In an embodiment, for example, the pixel electrode 221 may have a multi-layered structure of ITO/Ag/ITO.

A pixel defining layer 225 may cover an edge of the pixel electrode 221. The pixel defining layer 225 may define an opening OP. The opening OP may expose a center portion of the pixel electrode 221. The opening OP may define an emission area of light emitted by the organic light-emitting diode OLED. According to an embodiment, a width of the opening OP in the second direction (e.g., the y direction) may be defined as the size of the opening OP. The width of the opening OP in the second direction (e.g., the y direction) may be about 117 um. According to an embodiment, the pixel defining layer 225 may include an organic material and/or an inorganic material. According to an embodiment, the pixel defining layer 225 may be transparent. According to some embodiments, the pixel defining layer 225 may include a black matrix. In this case, the pixel defining layer 225 may be opaque.

The intermediate layer 222 may include a first functional layer 222a, an emission layer 222b, and a second functional layer 222c. The emission layer 222b may include a low molecular weight or high molecular weight organic material that emits light of a certain color. According to an embodiment, at least one selected from the first functional layer 222a and the second functional layer 222c may be a common layer disposed throughout the display area. The first functional layer 222a may include a hole transport layer (HTL), or may include an HTL and a hole injection layer (HIL). The second functional layer 222c may include an electron transport layer (ETL) and/or an electron injection layer (EIL). According to some embodiments, the second functional layer 222c may be omitted.

The opposite electrode 223 may be disposed on the emission layer 222b. The opposite electrode 223 may include a conductive material having a low work function. In an embodiment, for example, the opposite electrode 223 may include a (semi) transparent layer including, for example, silver (Ag), magnesium (Mg), aluminum (Al), platinum (Pt), palladium (Pd), gold (Au), nickel (Ni), neodymium (Nd), iridium (Ir), chromium (Cr), lithium (Li), calcium (Ca) or an alloy of these materials. Alternatively, the opposite electrode 223 may further include a layer, such as ITO, IZO, ZnO, or In₂O₃, on the (semi)transparent layer including any of the above-described materials.

According to some embodiments, a capping layer (not shown) may be further located on the opposite electrode 223. The capping layer may include lithium fluoride (LiF), an inorganic material, or/and an organic material.

The first encapsulation member 300 (see FIG. 4) may be disposed on the first display layer 200. Referring to FIG. 8, the first encapsulation member 300 (see FIG. 4) may include an encapsulation substrate 310. According to an embodiment, a thickness of the encapsulation substrate 310 in a direction perpendicular to the first substrate 100 may be about 450 μm. Although not shown in FIG. 8, the first display layer 200 may be sealed by the sealing member 320 (see FIG. 4) interposed between the encapsulation substrate 310 and the first substrate 100.

The first anti-reflection layer 400 may be disposed on the first encapsulation member 300 of FIG. 4, and the first light path control layer 500 may be disposed on the first anti-reflection layer 400. A first adhesive layer ADL may be disposed between the first light path control layer 500 and the first anti-reflection layer 400. The first adhesive layer ADL may be a transparent adhesive member such as an OCA film. According to an embodiment, a thickness of the first adhesive layer ADL in the direction perpendicular to the first substrate 100 may be about 100 μm.

The first light path control layer 500 may include the first lower layer 510, the plurality of first light-shielding lines 530, and the first upper layer 520. The first lower layer 510 may include a transparent resin. According to an embodiment, the first lower layer 510 may include a plurality of grooves. The plurality of grooves may be arranged at regular intervals. The plurality of first light-shielding lines 530 may fill the plurality of grooves, respectively. The plurality of first light-shielding lines 530 may be spaced apart from one another at constant intervals in the second direction (e.g., the y direction). The plurality of first light-shielding lines 530 may each include a light-shielding material. The first upper layer 520 may be disposed on the first lower layer 510 and the plurality of first light-shielding lines 530. The first upper layer 520 may include a polymer resin. In an embodiment, for example, the first upper layer 520 may include polycarbonate.

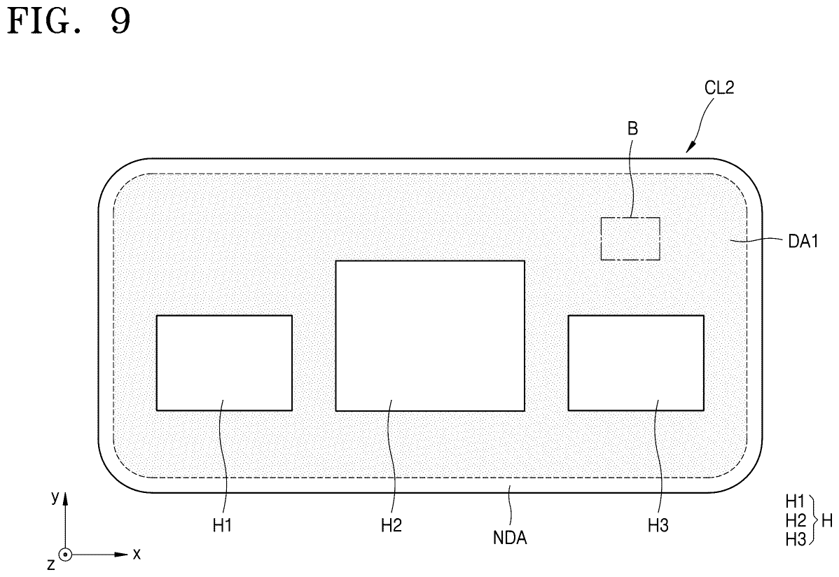

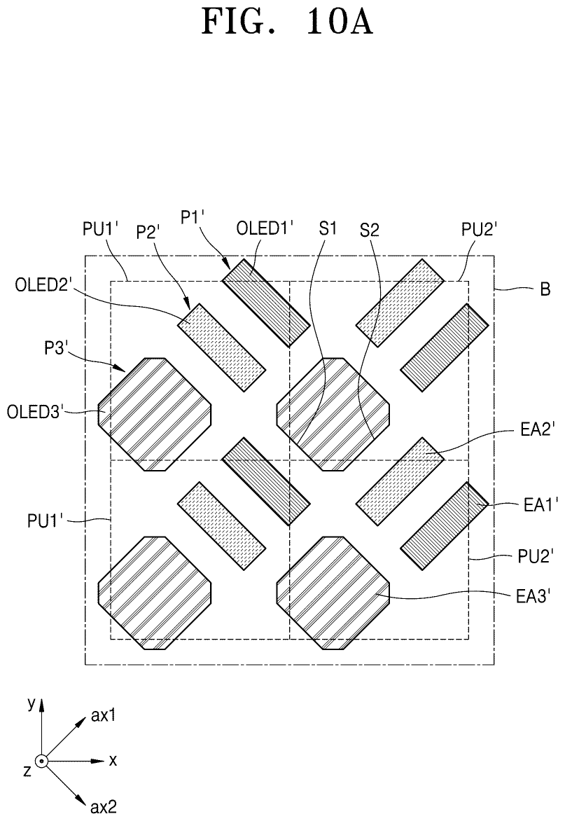

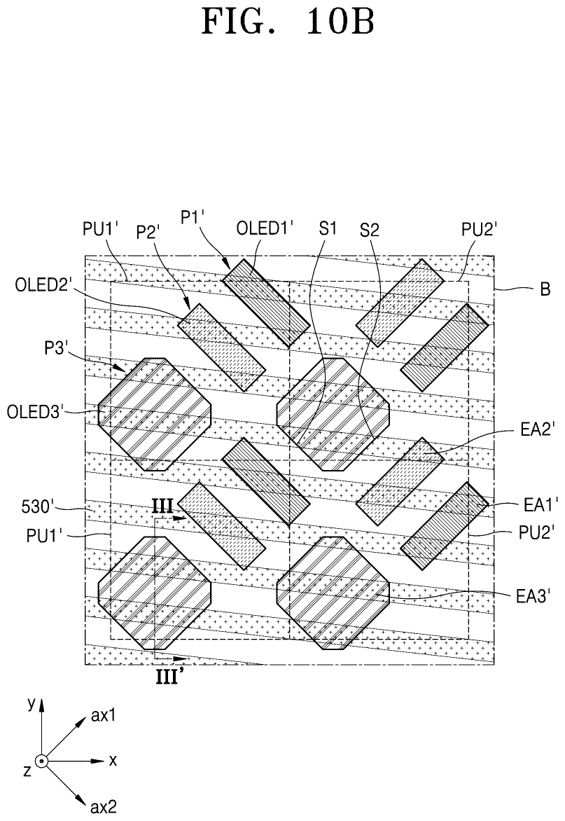

FIG. 9 is a schematic plan view of the second cluster panel CL2 included in a display apparatus according to an embodiment. FIGS. 10A and 10B are schematic plan views of a portion of a display apparatus according to an embodiment, and are enlarged views of a region B of the display apparatus of FIG. 9.

In an embodiment, referring to FIG. 9, the second cluster panel CL2 may include at least one hole H defined through the second cluster panel CL2. The at least one hole H may include a first hole H1, a second hole H2, and a third hole H3, as shown in FIG. 8. The first hole H1, the second hole H2, and the third hole H3 may be located in the center portion of the second cluster panel CL2 in a plan view, and may be arranged apart from each other.

According to an embodiment, the first hole H1 may correspond to the third display area DA3 (see FIG. 6) of the first cluster panel CL1 (see FIG. 6), the second hole H2 may correspond to the second display area DA2 (see FIG. 6) of the first cluster panel CL1 (see FIG. 6), and the third hole H3 may correspond to the fourth display area DA4 (see FIG. 6) of the first cluster panel CL1 (see FIG. 6). That is, although the second cluster panel CL2 is disposed over the first cluster panel CL1 (see FIG. 6), a user may recognize an image implemented by the first cluster panel CL1 through the at least one hole H of the second cluster panel CL2.

The second cluster panel CL2 may include a first display area DA1. The first display area DA1 may be an area excluding the at least one hole H among the planar area of the second cluster panel CL2. The first display area DA1 may surround the at least one hole H. In other words, the first display area DA1 may be an area that surrounds each of the second display area DA2 (see FIG. 6), the third display area DA3 (see FIG. 6), and the fourth display area DA4 (see FIG. 6).

Next, referring to FIG. 10A, a plurality of subpixels P (see FIG. 3A) may be arranged in the first display area DA1. The plurality of subpixels P (see FIG. 3A) may include a first subpixel P1′, a second subpixel P2′, and a third subpixel P3′ that emit light of different colors. Each of the first subpixel P1′, the second subpixel P2′, and the third subpixel P3′ may be provided in plurality. The first subpixel P1′ may emit red light like the first subpixel P1 of FIG. 6, the second subpixel P2′ may emit green light like the second subpixel P2 of FIG. 6, and the third subpixel P3′ may emit blue light like the third subpixel P3 of FIG. 6.

According to an embodiment, an arrangement structure and arrangement direction of the plurality of subpixels P (see FIG. 3A) arranged in the first display area DA1 may be the same as those of the plurality of subpixels P (see FIG. 3A) arranged in the second display area DA2 (see FIG. 6). In other words, an arrangement structure and arrangement direction of the first subpixel P1, the second subpixel P2, and the third subpixel P3 arranged in the first cluster panel CL1 (see FIG. 6) may be the same as those of the first subpixel P1′, the second subpixel P2′, and the third subpixel P3′ arranged in the cluster panel CL2.

In an embodiment, for example, the first subpixel P1′ and the second subpixel P2′ may each have a rectangular shape, and the third subpixel P3′ may have a square or chamfered square shape. The first subpixel P1′, the second subpixel P2′, and the third subpixel P3′ may be tilted to form an angle of 45 degrees with respect to either the first direction (e.g., the x direction) or the second direction (e.g., the y direction).

A first pixel unit PU1′ and a second pixel unit PU2′ may be disposed in the first display area DA1. Similar to each of the first pixel unit PU1 (see FIG. 7A) and the second pixel unit PU2 (see FIG. 7A), each the first pixel unit PU1′ and the second pixel unit PU2′ may be a subpixel assembly including the first subpixel P1′, the second subpixel P2′, and the third subpixel P3′. The first pixel unit PU1′ may have the same structure as the first pixel unit PU1 (see FIG. 7A), and the second pixel unit PU2′ may have the same structure as the second pixel unit PU2 (see FIG. 7A). in an embodiment, for example, the first pixel unit PU1′ may have a structure in which a longer side of the first subpixel P1′ faces a longer side of the second subpixel P2′ and another longer side of the second subpixel P2′ faces one side of the third subpixel P3′. The second pixel unit PU2′ may have a structure in which a longer side of the first subpixel P1′ faces a longer side of the second subpixel P2′ and a shorter side of the first subpixel P1′ and a shorter side of the second subpixel P2′ face one side of the third subpixel P3′.

In this case, the first pixel units PU1′ and the second pixel units PU2′ may be repeatedly arranged in the first display area DA1. According to an embodiment, the first pixel units PU1′ may be consecutively arranged in the second direction (e.g., the y direction), and the second pixel units PU2′ may also be consecutively arranged in the second direction (e.g., the y direction). The first pixel units PU1′ and the second pixel units PU2′ may be alternately arranged in the first direction (e.g., the x direction). In other words, an arrangement direction of the plurality of subpixels P (see FIG. 3A) arranged in the first display area DA1 may be the same as that of the plurality of subpixels P (see FIG. 3A) arranged in the second display area DA2.

In an embodiment, referring to FIG. 10B, the second cluster panel CL2 may include a plurality of second light-shielding lines 530′. The plurality of second light-shielding lines 530′ may each extend substantially in the first direction (e.g., the x direction). in an embodiment, the plurality of second light-shielding lines 530′ may each extend at an angle of about 5 degrees or less with respect to the first direction (e.g., the x direction). According to an embodiment, the plurality of second light-shielding lines 530′ may each extend at the same inclination as the plurality of first light-shielding lines 530 of FIG. 7B.

Through such a structure described above, the display apparatus according to an embodiment may form uniform luminance throughout the display area DA (see FIG. 3A) despite a stacked structure of different panels.

In an embodiment, even when an arrangement structure of the plurality of subpixels P (see FIG. 3A) disposed in the first cluster panel CL1 (see FIG. 6) is the same as that of the plurality of subpixels P (see FIG. 3A) disposed in the second cluster panel CL2, when an arrangement direction of the plurality of subpixels P (see FIG. 3A) disposed in the first cluster panel CL1 (see FIG. 6) is the same as that of the plurality of subpixels P (see FIG. 3A) disposed in the second cluster panel CL2, the first display area DA1 and the second display area DA2 (see FIG. 6) may have different luminances from each other. In an embodiment, for example, the first pixel units PU1 (see FIG. 7A) disposed on the first cluster panel CL1 (see FIG. 6) are consecutively arranged in the second direction (e.g., the y direction) and the first pixel units PU1′ (see FIG. 7A) disposed on the second cluster panel CL2 are consecutively arranged in the first direction (e.g., the x direction), a luminance difference between the first cluster panel CL1 (see FIG. 6) and the second cluster panel CL2 may be generated. In detail, because each of the plurality of first light-shielding lines 530 (see FIG. 7B) and the plurality of second light-shielding lines 530′ extends at a specific inclination, even when only the arrangement direction of the plurality of subpixels P (see FIG. 3A) is different, a luminance deviation and moire issues may occur.

Accordingly, in the display apparatus according to an embodiment, the plurality of subpixels P (see FIG. 3A) disposed in each of the first cluster panel CL1 (see FIG. 6) and the second cluster panel CL2 are formed in the same structure and the same arrangement direction and also the plurality of first light-shielding lines 530 (see FIG. 7B) and the plurality of second light-shielding lines 530′ are formed at the same inclination, and thus a luminance deviation and moire issues may be effectively prevented from occurring.

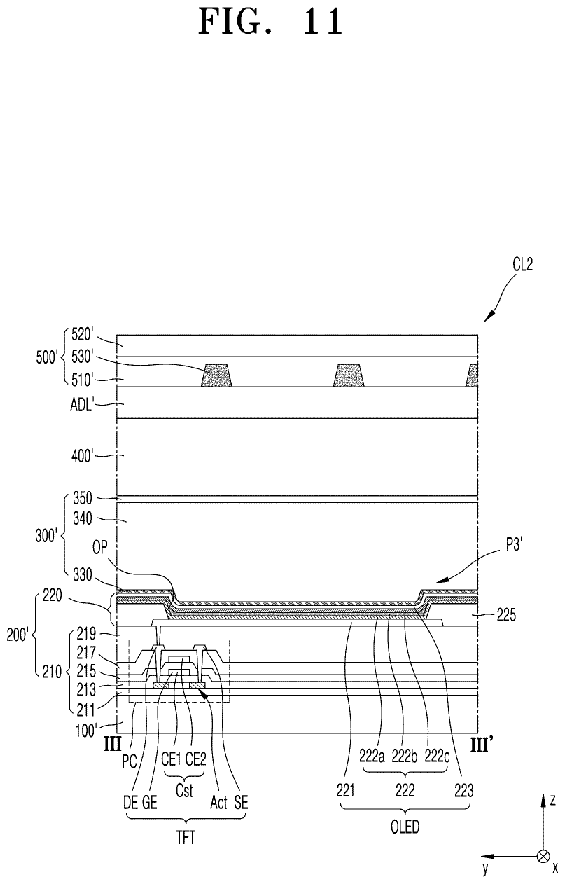

FIG. 11 is a schematic cross-sectional view of a portion of a display apparatus according to an embodiment, and illustrates a schematic cross-section of the display apparatus of FIG. 10B taken along line III-III′. FIG. 11 is a schematic cross-sectional view of a portion of the second cluster panel CL2, and reference numerals in FIG. 11 that are the same as or similar to the reference numerals in FIGS. 4 and 8 denote the same or like elements, and thus any repetitive detailed descriptions thereof will be omitted.

Referring to FIG. 11, in an embodiment, the second cluster panel CL2 may include a second substrate 100′, a second display layer 200′, a second encapsulation member 300′, a second anti-reflection layer 400′, a second adhesive layer ADL′, and a second light path control layer 500′. The second display layer 200′ may be disposed on the second substrate 100′. Similar to the first display layer 200 of FIG. 8, the second display layer 200′ may include a pixel circuit layer 210 and a light-emitting element layer 220. The pixel circuit layer 210 and the light-emitting element layer 220 included in the second display layer 200′ may be substantially the same as the first display layer 200 (see FIG. 8). However, embodiments are not limited thereto, and the first display layer 200 (see FIG. 8) and the second display layer 200′ may have different structures from each other.

The second encapsulation member 300′ may be disposed on the second display layer 200′. The second encapsulation member 300′ may cover the second display layer 200′ to protect the second display layer 200′ from moisture, oxygen, or the like from the outside. The second encapsulation member 300′ may include at least one inorganic encapsulation layer and at least one organic encapsulation layer. In an embodiment, for example, the second encapsulation member 300′ may include a first inorganic encapsulation layer 330, an organic encapsulation layer 340, and a second inorganic encapsulation layer 350.

The first and second inorganic encapsulation layers 330 and 350 may include at least one inorganic insulating material such as silicon oxide (SiO2), silicon nitride (SiNx), silicon oxynitride (SiOxNy), aluminum oxide (Al2O3), titanium oxide (TiO2), tantalum oxide (Ta2O5), hafnium oxide (HfO2), or zinc oxide (ZnO2), and may be formed by chemical vapor deposition (CVD) or the like. The organic encapsulation layer 340 may include a polymer-based material. Examples of the polymer-based material may include a silicon-based resin, an acryl-based resin (e.g., polymethyl methacrylate, polyacrylic acid, or the like), an epoxy-based resin, polyimide, and polyethylene.

Because the first inorganic encapsulation layer 330 provides high step coverage, an upper surface thereof may not be flat. However, the organic encapsulation layer 340 has a substantially flat upper surface, and accordingly, the second inorganic encapsulating layer 350 on the organic encapsulating layer 340 may also have a substantially flat upper surface.

The second anti-reflection layer 400′ may be disposed on the second encapsulation member 300′, and the second light path control layer 500′ may be disposed on the second anti-reflection layer 400′. The second adhesive layer ADL′ may be disposed between the second light path control layer 500′ and the second anti-reflection layer 400′, and the second adhesive layer ADL′ may be a transparent adhesive member such as an OCA film.

The second light path control layer 500′ may include a second lower layer 510′, a plurality of second light-shielding lines 530′, and a second upper layer 520′. The second lower layer 510′ may include transparent resin and may include a plurality of grooves. The plurality of second light-shielding lines 530′ may fill the plurality of groove, respectively, and may be spaced apart from each other at constant intervals in the second direction (e.g., the y direction). The plurality of second light-shielding lines 530′ may each include a light-shielding material. The second upper layer 520′ may be disposed on the second lower layer 510′ and the plurality of second light-shielding lines 530′. The second upper layer 520′ may include a polymer resin.

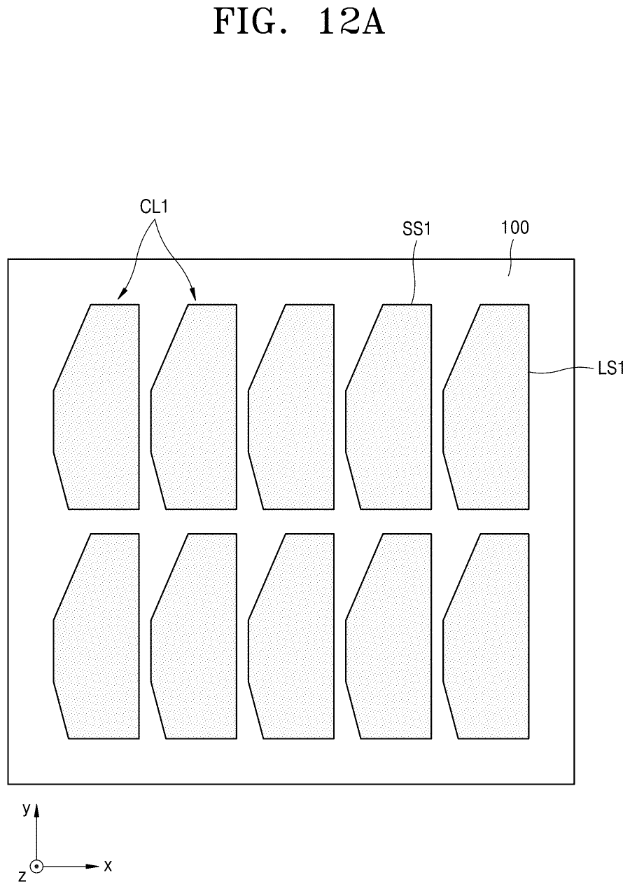

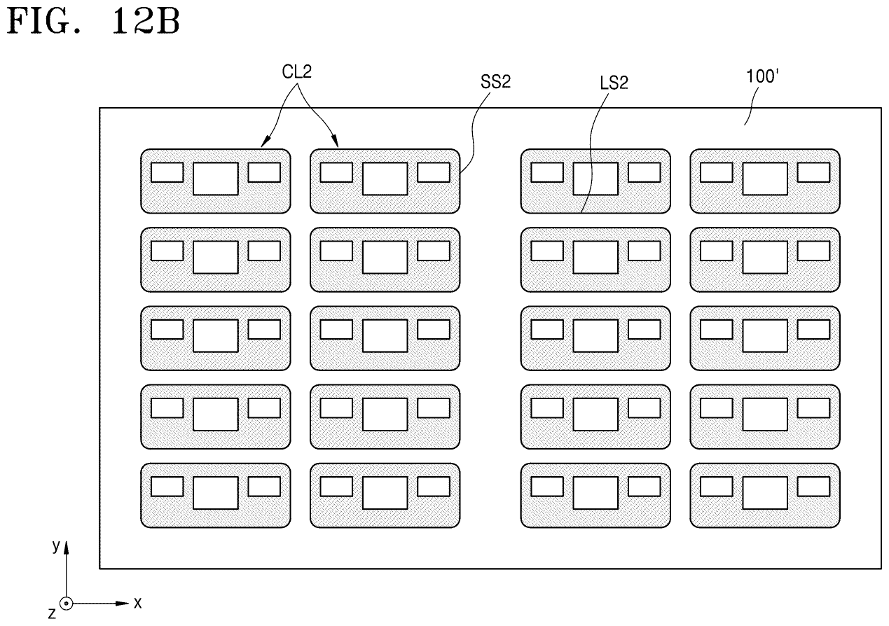

FIG. 12A is a layout diagram schematically showing locations of first cluster panels CL1 formed on the first substrate 100. FIG. 12B is a layout diagram schematically showing locations of second cluster panels CL2 formed on the second substrate 100′.

First, referring to FIG. 12A, a plurality of first cluster panels CL1 may be arranged on the first substrate 100. Depending on the size of the first substrate 100, the plurality of first cluster panels CL1 may be arranged as many as possible to suit the characteristics of the first substrate 100. According to an embodiment, the plurality of first cluster panels CL1 may be arranged in a way such that a longer side LS1 of a first cluster panel CL1 is parallel to a shorter side of the first substrate 100 and a shorter side SS1 of the first cluster panel CL1 is parallel to a longer side of the first substrate 100.

Referring to FIG. 12B, a plurality of second cluster panels CL2 may be arranged on the second substrate 100′. Depending on the size of the second substrate 100′, the plurality of second cluster panels CL2 may be arranged as many as possible to suit the characteristics of the second substrate 100′. According to an embodiment, the plurality of second cluster panels CL2 may be arranged in a way such that a longer side LS2 of a second cluster panel CL2 is parallel to a longer side of the second substrate 100′ and a shorter side SS2 of the second cluster panel CL2 is parallel to a shorter side of the second substrate 100′.

That is, the plurality of first cluster panels CL1 may be arranged in a way such that each of their longer sides extends in the second direction (e.g., the y direction), and the plurality of second cluster panels CL2 may be arranged in a way such that each of their longer sides extends in the first direction (e.g., the x direction). When an arrangement direction of the first cluster panels CL1 is different from that of the second cluster panels CL2 as described above, and the plurality of subpixels P (see FIG. 3A) are equally formed in the first substrate 100 and the second substrate 100′, an arrangement direction of the plurality of subpixels P (see FIG. 3A) formed in the first display area DA1 (see FIG. 9) is different from that of the plurality of subpixels P (see FIG. 3A) formed in the second display area DA2 (see FIG. 6). As described above, the plurality of subpixels P (see FIG. 3A) formed in the first display area DA1 (see FIG. 9) and the second display area DA2 (see FIG. 6) are desired to have not only the same arrangement structure but also the same arrangement direction, to prevent a luminance deviation from occurring.

Accordingly, in the display apparatus according to an embodiment, the plurality of subpixels P (see FIG. 3A) formed in the first cluster panel CL1 are rotated by 90 degrees, so that the arrangement direction of the plurality of subpixels P (see FIG. 3A) in the first display area DA1 (see FIG. 6) may be aligned to be the same as to that of the plurality of subpixels P (see FIG. 3A) in the second display area DA2 (see FIG. 9). In this case, the plurality of subpixels P (see FIG. 3A) may be formed in the first cluster panel CL1 in a direction rotated by 90 degrees by improving a method of stretching or mounting the frame of a fine metal mask (FMM) in equipment. In detail, not only the software of an FMM stretcher is desired to be modified, but also a separate scanning method may be desired when distortion of the plurality of subpixels P (see FIG. 3A) is inspected. Accordingly, the display apparatus according to an embodiment that may be formed through such a modification process as described above may eliminate a luminance deviation and prevent moire issues, thereby implementing an image of high quality.

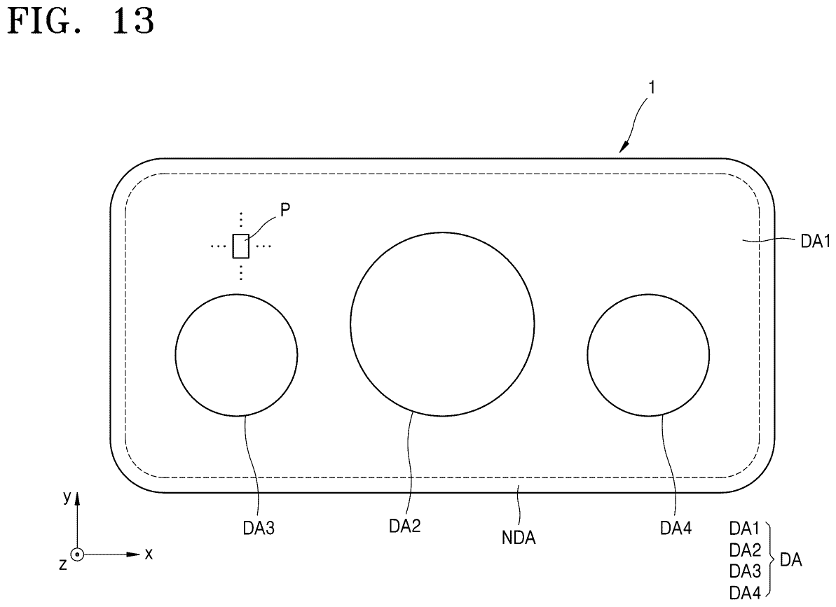

FIG. 13 is a schematic plan view of a display apparatus according to another embodiment. Referring to FIG. 13, other features except for the features of the second, third, and fourth display areas DA2, DA3, and DA4 are the same as those described above with reference to FIGS. 3A through 3C. Accordingly, any repetitive detailed descriptions of the same or like components in FIG. 13 as those described above with reference to FIGS. 3A through 3C will be omitted, and differences therebetween will be mainly described below.

Referring to FIG. 13, an embodiment of the display apparatus 1 may include a display area DA and a non-display area NDA. A subpixel P may be arranged in the display area DA. The display area DA may include a first display area DA1, a second display area DA2, a third display area DA3, and a fourth display area DA4. The second display area DA2, the third display area DA3, and the fourth display area DA4 may be disposed inside the first display area DA1 and may be entirely surrounded by the first display area DA1.

According to an embodiment, the second display area DA2, the third display area DA3, and the fourth display area DA4 may have circular shapes in a plan view as shown in FIG. 13. However, embodiments are not limited thereto and the second display area DA2, the third display area DA3, and the fourth display area DA4 may have oval shapes. In other words, at least one hole H (see FIG. 9) included in the second cluster panel CL2 (see FIG. 9) may have a circular shape in a plan view.

Accordingly, a vehicle according to another embodiment may display images on the second display area DA2, the third display area DA3, and the fourth display area DA4 each having a circular shape, in a driving mode. However, similar to FIG. 3C, the vehicle according to another embodiment may also display images on the entirety of the first, second, third, and fourth display areas DA1, DA2, DA3, and DA4 in a non-driving mode. As the second, third, and fourth display areas DA2, DA3, and DA4 are formed in various shapes as described above, the vehicle according to another embodiment may be variously designed to thereby improve its aesthetic appeal.

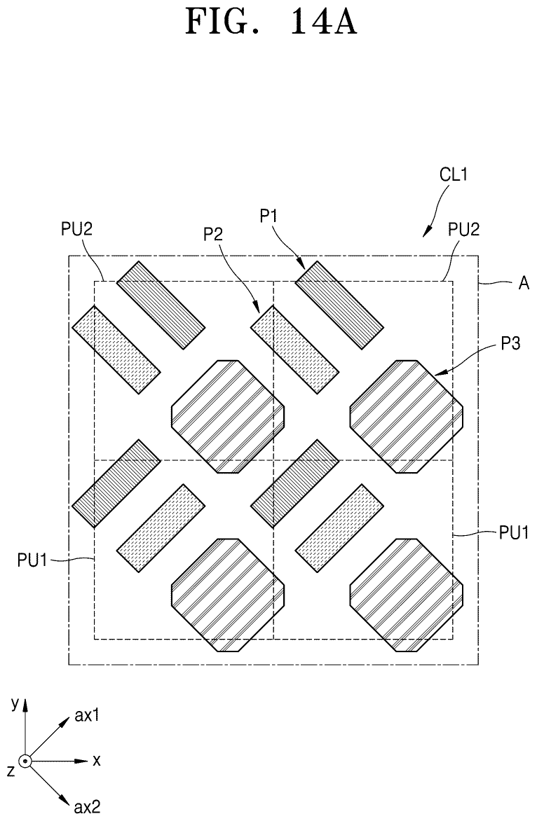

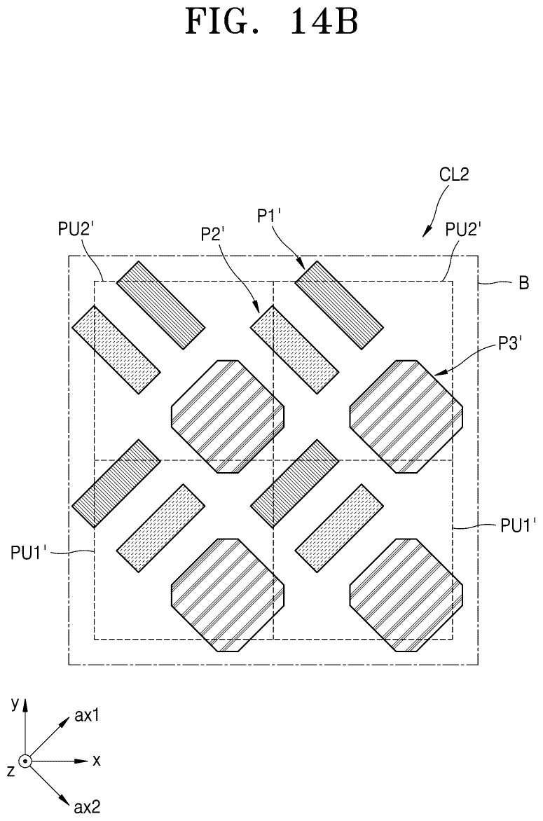

FIGS. 14A and 14B are schematic plan views of portions of a display apparatus according to another embodiment, respectively. Referring to FIGS. 14A and 14B, other features except for the arrangement direction of the plurality of subpixels P (see FIG. 3A) are the same as those described above with reference to FIGS. 6 through 11. Accordingly, any repetitive detailed descriptions of the same or like components in FIGS. 14A and 14B as those described above with reference to FIGS. 6 through 11 will be omitted, and differences therebetween will be mainly described below.

In an embodiment, referring to FIG. 14A, a plurality of subpixels P (see FIG. 3A) may be arranged in a first cluster panel CL1. The plurality of subpixels P (see FIG. 3A) may include a first subpixel P1 that emits red light, a second subpixel P2 that emits green light, and a third subpixel P3 that emits blue light. Each of the first subpixel P1, the second subpixel P2, and the third subpixel P3 may be provided in plurality.

A first pixel unit PU1 and a second pixel unit PU2 may be disposed in the first cluster panel CL1. The first pixel unit PU1 and the second pixel unit PU may be disposed adjacent to each other. Each of the first pixel unit PU1 and the second pixel unit PU2 may be a subpixel assembly including the first subpixel P1, the second subpixel P2, and the third subpixel P3.

According to an embodiment, the first pixel unit PU1 may have a structure in which a longer side of the first subpixel P1 faces a longer side of the second subpixel P2 and another longer side of the second subpixel P2 faces one side of the third subpixel P3. In the first pixel unit PU1, the third subpixel P3, the second subpixel P2, and the first subpixel P1 may be sequentially arranged in the fourth direction (e.g., the ax2 direction). In other words, the longer sides of the first subpixel P1 and the longer sides of the second subpixel P2 may be parallel to one side of the third subpixel P3 extending in the third direction (e.g., the ax1 direction).

According to an embodiment, the second pixel unit PU2 may have a structure in which a longer side of the first subpixel P1 faces a longer side of the second subpixel P2 and a shorter side of the first subpixel P1 and a shorter side of the second subpixel P2 face one side of the third subpixel P3. In other words, the shorter sides of the first subpixel P1 and the shorter sides of the second subpixel P2 may be parallel to one side of the third subpixel P3 extending in the third direction (e.g., the ax1 direction).

In such an embodiment, the first pixel units PU1 and the second pixel units PU2 may be repeatedly arranged in the first cluster panel CL1. According to an embodiment, the first pixel units PU1 may be consecutively arranged in the first direction (e.g., the x direction), and the second pixel units PU2 may also be consecutively arranged in the first direction (e.g., the x direction). The first pixel units PU1 and the second pixel units PU2 may be alternately arranged in the second direction (e.g., the y direction).

In an embodiment, referring to FIG. 14B, a plurality of subpixels P (see FIG. 3A) may be arranged in a second cluster panel CL2. The plurality of subpixels P (see FIG. 3A) may include a first subpixel P1′ that emits red light, a second subpixel P2′ that emits green light, and a third subpixel P3′ that emits blue light. Each of the first subpixel P1′, the second subpixel P2′, and the third subpixel P3′ may be provided in plurality.

According to an embodiment, an arrangement structure and arrangement direction of the plurality of subpixels P (see FIG. 3A) arranged in the first display area DA1 (see FIG. 9) of the second cluster panel CL2 may be the same as those of the plurality of subpixels P (see FIG. 3A) arranged in the second display area DA2 (see FIG. 6) of the first cluster panel CL1.

A first pixel unit PU1′ and a second pixel unit PU2′ may be disposed in the second cluster panel CL2. Similar to each of the first pixel unit PU1 (see FIG. 14A) and the second pixel unit PU2 (see FIG. 14A), each the first pixel unit PU1′ and the second pixel unit PU2′ may be a subpixel assembly including the first subpixel P1′, the second subpixel P2′, and the third subpixel P3′. The first pixel unit PU1′ may have the same structure as the first pixel unit PU1 (see FIG. 14A), and the second pixel unit PU2′ may have the same structure as the second pixel unit PU2 (see FIG. 14A). In an embodiment, for example, the first pixel unit PU1′ may have a structure in which a longer side of the first subpixel P1′ faces a longer side of the second subpixel P2′ and another longer side of the second subpixel P2′ faces one side of the third subpixel P3′. The second pixel unit PU2′ may have a structure in which a longer side of the first subpixel P1′ faces a longer side of the second subpixel P2′ and a shorter side of the first subpixel P1′ and a shorter side of the second subpixel P2′ face one side of the third subpixel P3′.

In this case, the first pixel units PU1′ may be consecutively arranged in the first direction (e.g., the x direction), and the second pixel units PU2′ may also be consecutively arranged in the first direction (e.g., the x direction). The first pixel units PU1′ and the second pixel units PU2′ may be alternately arranged in the second direction (e.g., the y direction). In other words, an arrangement direction of the plurality of subpixels P (see FIG. 3A) arranged in a display area of the first cluster panel CL1 may be the same as that of the plurality of subpixels P (see FIG. 3A) arranged in a display area of the second cluster panel CL2.

In an embodiment, as described above, an arrangement structure and an arrangement direction of the plurality of subpixels P (see FIG. 3A) disposed in the first cluster panel CL1 are the same as those of the plurality of subpixels P (see FIG. 3A) disposed in the second cluster panel CL2, such that a luminance deviation may be effectively prevented. That is, even when the first pixel units PU1, the first pixel units PU1′, the second pixel units PU2, and the second pixel units PU2′ are individually sequentially arranged in the first direction (e.g., the x direction) as shown in FIGS. 14A and 14B, as long as only the arrangement direction is the same between the display areas, luminance may be maintained uniform. Therefore, the display apparatus according to an embodiment may also eliminate a luminance deviation and prevent moire issues, thereby implementing an image of high quality.

A display apparatus according to an embodiment as described above may implement images of high quality by securing uniform luminance and effectively preventing occurrence of moire. These effects are only examples, and the scope of the disclosure is not limited thereto.

The invention should not be construed as being limited to the embodiments set forth herein. Rather, these embodiments are provided so that this disclosure will be thorough and complete and will fully convey the concept of the invention to those skilled in the art.

While the invention has been particularly shown and described with reference to embodiments thereof, it will be understood by those of ordinary skill in the art that various changes in form and details may be made therein without departing from the spirit or scope of the invention as defined by the following claims.

What is claimed is:

1. A display apparatus comprising:
a first panel including a first substrate and a first display layer disposed on the first substrate; and
a second panel including a second substrate disposed on the first panel and a second display layer disposed on the second substrate,
wherein the second panel includes a first display area defined by the second display layer, and at least one hole is defined through the second panel,
the first panel includes a second display area defined by the first display layer and overlapping the at least one hole, and
an arrangement structure and an arrangement direction of a plurality of subpixels arranged in the first display area are respectively the same as an arrangement structure and an arrangement direction of a plurality of subpixels arranged in the second display area.

2. The display apparatus of claim 1, wherein
the plurality of subpixels include a first subpixel which emits red light, a second subpixel which emits green light, and a third subpixel which emits blue light, and
each of the first subpixel and the second subpixel has a rectangular shape in a plan view.

3. The display apparatus of claim 2, wherein
the third subpixel has a square shape or chamfered square shape in a plan view.

4. The display apparatus of claim 2, wherein
each of the first display area and the second display area includes a first pixel unit and a second pixel unit arranged adjacent to each other, and
each of the first pixel unit and the second pixel unit includes the first subpixel, the second subpixel, and the third subpixel.

5. The display apparatus of claim 4, wherein
the first pixel unit has an arrangement structure in which a longer side of the first subpixel faces a longer side of the second subpixel and another longer side of the second subpixel faces one side of the third subpixel, and
the second pixel unit has an arrangement structure in which a longer side of the first subpixel faces a longer side of the second subpixel and a shorter side of the first subpixel and a shorter side of the second subpixel face one side of the third subpixel.

6. The display apparatus of claim 4, wherein the second panel has longer sides each extending a first direction and shorter sides each extending in a second direction that intersects the first direction.

7. The display apparatus of claim 6, wherein
the first pixel units are consecutively arranged in the second direction,
the second pixel units are consecutively arranged in the second direction, and
the first pixel units and the second pixel units are arranged alternately in the first direction.

8. The display apparatus of claim 6, wherein
the first pixel units are consecutively arranged in the first direction,
the second pixel units are consecutively arranged in the first direction, and
the first pixel units and the second pixel units are arranged alternately in the second direction.

9. The display apparatus of claim 1, wherein
the first panel is disposed on the first display layer and further includes a first light path control layer including a plurality of first light-shielding lines,
the second panel is disposed on the second display layer and further includes a second light path control layer including a plurality of second light-shielding lines, and
in a plan view, the plurality of first light-shielding lines and the plurality of second light-shielding lines each extend while being inclined at a same angle as each other.

10. The display apparatus of claim 1, wherein the at least one hole has a polygonal shape or a circular shape.

11. The display apparatus of claim 1, wherein
the first panel further includes a first encapsulation member covering the first display layer, and
the second panel further includes a second encapsulation member covering the second display layer.

12. The display apparatus of claim 11, wherein
the first encapsulation member includes an encapsulation substrate and a sealing member disposed between the encapsulation substrate and the first substrate, and
the second encapsulation member comprises at least one inorganic encapsulation layer and at least one organic encapsulation layer.

13. The display apparatus of claim 11, wherein each of the first encapsulation member and the second encapsulation member comprises at least one inorganic encapsulation layer and at least one organic encapsulation layer.

14. The display apparatus of claim 1, further comprising:
an adhesive member interposed between the first panel and the second panel.

15. The display apparatus of claim 1, further comprising:
a cover window disposed on the second panel.

16. A vehicle comprising:
side window glasses spaced apart from each other in a first direction; and
a display apparatus disposed between the side window glasses,
wherein the display apparatus comprises:
a first panel including a first substrate and a first display layer disposed on the first substrate; and
a second panel including a second substrate disposed on the first panel and a second display layer disposed on the second substrate,
the second panel includes a first display area defined by the second display layer, and at least one hole is defined through the second panel,
the first panel includes a second display area defined by the first display layer and overlapping the at least one hole, and
wherein an arrangement structure and an arrangement direction of a plurality of subpixels arranged in the first display area are respectively the same as an arrangement structure and an arrangement direction of a plurality of subpixels arranged in the second display area.

17. The vehicle of claim 16, wherein
the first panel is disposed on the first display layer and further includes a first light path control layer including a plurality of first light-shielding lines,
the second panel is disposed on the second display layer and further includes a second light path control layer including a plurality of second light-shielding lines, and
in a plan view, the plurality of first light-shielding lines and the plurality of second light-shielding lines each extend while being inclined at a same angle as each other.

18. The vehicle of claim 16, wherein the display apparatus is disposed in a cluster located in front of a steering wheel.

19. The vehicle of claim 16, wherein the first display area and the second display area are independently driven.

20. The vehicle of claim 19, wherein the display apparatus displays an image on the second display area in a driving mode, and displays an image on both of the first display area and the second display area in a non-driving mode.
